(19) United States
(12) Patent Application Publication
(10) Pub. No.: US 2023/0420462 A1
(43) Pub. Date: Dec. 28, 2023

(54) ARRAY SUBSTRATE, PREPARATION METHOD THEREOF, DISPLAY PANEL AND DISPLAY DEVICE

(71) Applicant: Xiamen Tianma Display Technology Co., Ltd., Xiamen (CN)

(72) Inventor: Feng XIE, Xiamen (CN)

(73) Assignee: Xiamen Tianma Display Technology Co., Ltd., Xiamen (CN)

(21) Appl. No.: 18/243,942

(22) Filed: Sep. 8, 2023

(30) Foreign Application Priority Data
May 17, 2023 (CN) 202310559409.6

(51) Int. Cl. H01L 27/12

(52) U.S. Cl. CPC H01L 27/1225; H01L 27/127

(57) ABSTRACT

Provided are an array substrate, a preparation method thereof, a display panel and a display device. The array substrate includes a substrate and at least one transistor located on a side of the substrate. Each transistor of the at least one transistor includes an active layer, a first ohmic contact layer, a first gate and a first electrode. The active layer includes metal oxide. The first ohmic contact layer is in contact connection with a first ohmic contact region of the active layer. The first electrode is electrically connected to the first ohmic contact layer.

### CROSS-REFERENCE TO RELATED APPLICATION

This application claims priority to Chinese Patent Application No. CN 202310559409.6, filed on May 17, 2023, the disclosure of which is incorporated herein by reference in its entirety.

### TECHNICAL FIELD

The present application relates to the field of display technologies and, in particular, to an array substrate, a preparation method thereof, a display panel and a display device.

### BACKGROUND

A display panel generally includes pixel driving circuits and a drive signal line for providing drive signals for the pixel driving circuits. Transistors are disposed inside the pixel driving circuits and often use metal oxide as the active layer. However, the transistors using metal oxide as the active layer have a relatively poor stability and has a problem of having a relatively small on-state current.

### SUMMARY

The present application provides an array substrate, a preparation method thereof, a display panel and a display device to improve the stability of a transistor and increase the on-state current of the transistor.

According to an aspect of the present application, an array substrate is provided. The array substrate includes a substrate and at least one transistor located on a side of the substrate, where a transistor of the at least one transistor includes an active layer, a first ohmic contact layer, a first gate and a first electrode, and the active layer includes metal oxide. Along a thickness direction of the substrate, the first ohmic contact layer is located on a side of the active layer facing away from the substrate, and the first electrode and the first gate are located on a side of the first ohmic contact layer facing away from the substrate. The active layer includes a channel region and a first ohmic contact region, and a vertical projection of the first gate on the active layer overlaps the channel region. The first ohmic contact layer is in contact connection with the first ohmic contact region of the active layer, and the first electrode is electrically connected to the first ohmic contact layer.

According to another aspect of the present application, a preparation method for an array substrate is provided and includes the steps below.

An active layer, a first ohmic contact layer, a first gate and a first electrode are prepared on a side of the substrate to form at least one transistor, where the active layer is metal oxide; along a thickness direction of the substrate, the first ohmic contact layer is located on a side of the active layer facing away from the substrate, and the first electrode and the first gate are located on a side of the first ohmic contact layer facing away from the substrate; the active layer includes a channel region and a first ohmic contact region, and a vertical projection of the first gate on the active layer coincides with the channel region; and the first ohmic contact layer is in contact connection with the first ohmic contact region of the active layer, and the first electrode is electrically connected to the first ohmic contact layer.

According to another aspect of the present application, a display panel is provided and includes the array substrate described above.

According to another aspect of the present application, a display device is provided and includes the display panel described above.

It is to be understood that the content described in this section is neither intended to identify key or critical features of embodiments of the present application nor intended to limit the scope of the present application. Other features of the present application become easily understood through the description hereinafter.

### BRIEF DESCRIPTION OF DRAWINGS

To illustrate the technical solutions in embodiments of the present application more clearly, drawings used in the description of the embodiments are briefly described below. Apparently, the drawings described below only illustrate part of embodiments of the present application, and those of ordinary skill in the art may obtain other drawings based on the drawings on the premise that no creative work is done.

FIG. 1 is a diagram illustrating the structure of an array substrate according to embodiments of the present application.

FIG. 2 is an enlarged diagram illustrating the structure of part A of FIG. 1.

FIG. 3 is a sectional diagram taken along a direction B-B′ of FIG. 2.

FIG. 4 is a diagram illustrating the structure of a transistor in the related art.

FIG. 5 is a diagram illustrating the partial structure of an array substrate according to embodiments of the present application.

FIG. 6 is a sectional diagram taken along a direction C-C′ of FIG. 5.

FIG. 7 is a diagram illustrating a preparation method for a transistor according to embodiments of the present application.

FIG. 8 is a diagram illustrating the partial structure of another array substrate according to embodiments of the present application.

FIG. 9 is a sectional diagram taken along a direction D-D′ of FIG. 8.

FIG. 10 is a diagram illustrating a preparation method for another transistor according to embodiments of the present application.

FIG. 11 is a diagram illustrating the partial cross section structure of an array substrate according to embodiments of the present application.

FIG. 12 is a diagram illustrating the partial cross section structure of another array substrate according to embodiments of the present application.

FIG. 13 is a diagram illustrating the partial structure of another array substrate according to embodiments of the present application.

FIG. 14 is a sectional diagram taken along a direction E-E′ of FIG. 13.

FIG. 15 is a diagram illustrating the partial structure of another array substrate according to embodiments of the present application.

FIG. 16 is a sectional diagram taken along a direction F-F′ of FIG. 15.

FIG. 17 is a diagram illustrating the partial structure of another array substrate according to embodiments of the present application.

FIG. 18 is a sectional diagram taken along a direction G-G′ of FIG. 17.

FIG. 19 is a diagram illustrating the partial structure of another array substrate according to embodiments of the present application.

FIG. 20 is a sectional diagram taken along a direction H-H′ of FIG. 19.

FIG. 21 is a sectional diagram taken along a direction I-I′ of FIG. 19.

FIG. 22 is a diagram illustrating the partial structure of another array substrate according to embodiments of the present application.

FIG. 23 is a sectional diagram taken along a direction J-J′ of FIG. 22.

FIG. 24 is a flowchart of a preparation method for an array substrate according to embodiments of the present application.

FIG. 25 is a diagram illustrating a preparation method for an array substrate according to embodiments of the present application.

FIG. 26 is a diagram illustrating a preparation method for another array substrate according to embodiments of the present application.

FIG. 27 is a diagram illustrating the structure of a display panel according to embodiments of the present application.

FIG. 28 is a diagram illustrating the structure of another display panel according to embodiments of the present application.

FIG. 29 is a diagram illustrating the structure of a pixel driving circuit according to embodiments of the present application.

FIG. 30 is a diagram illustrating the structure of a display device according to embodiments of the present application.

### DETAILED DESCRIPTION

Technical solutions in embodiments of the present application are described clearly and completely in conjunction with drawings in embodiments of the present application from which technical solutions of the present application are better understood by those skilled in the art. Apparently, the embodiments described below are part, not all, of embodiments of the present application. Based on embodiments of the present application, all other embodiments obtained by those of ordinary skill in the art on the premise that no creative work is done are within the scope of the present application.

It is to be noted that terms such as “first” and “second” in the description, claims and drawings of the present application are used for distinguishing between similar objects and are not necessarily used for describing a particular order or sequence. It is to be understood that the data used in this manner are interchangeable in appropriate cases so that embodiments of the present application described herein can be implemented in an order not illustrated or described herein. In addition, the terms “including”, “having” or any other variations thereof described herein are intended to encompass a non-exclusive inclusion. For example, a process, method, system, product or device that includes a series of steps or units may include not only the expressly listed steps or units but also other steps or units that are not expressly listed or are inherent to such a process, method, system, product or device.

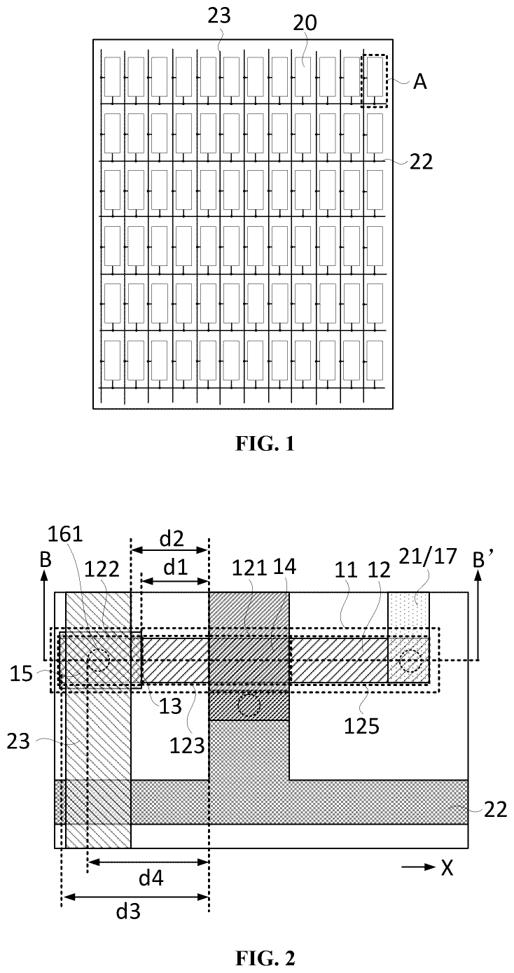

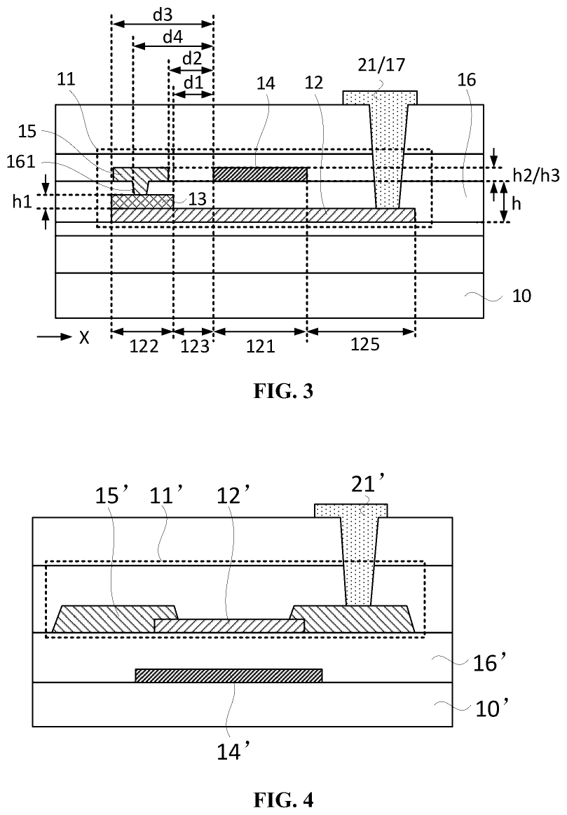

FIG. 1 is a diagram illustrating the structure of an array substrate according to embodiments of the present application. FIG. 2 is an enlarged diagram illustrating the structure of part A of FIG. 1. FIG. 3 is a sectional diagram taken along a direction B-B′ of FIG. 2. As shown in FIGS. 1 to 3, the array substrate according to this embodiment of the present application includes a substrate 10 and at least one transistor 11 located on a side of the substrate 10. A transistor 11 of the at least one transistor 11 includes an active layer 12, a first ohmic contact layer 13, a first gate 14 and a first electrode 15, and the active layer 12 includes metal oxide. Along the thickness direction of the substrate 10, the first ohmic contact layer 13 is located on a side of the active layer 12 facing away from the substrate 10, and the first electrode 15 and the first gate 14 are located on a side of the first ohmic contact layer 13 facing away from the substrate 10. The active layer 12 includes a channel region 121 and a first ohmic contact region 122, the vertical projection of the first gate 14 on the active layer 12 overlaps the channel region 121, the first ohmic contact layer 13 is in contact connection with the first ohmic contact region 122 of the active layer 12, and the first electrode 15 is electrically connected to the first ohmic contact layer 13.

In an embodiment, as shown in FIGS. 1 to 3, the substrate 10 is provided with multiple pixel driving circuits 20. The multiple pixel driving circuits 20 may be electrically connected to light-emitting elements (not shown in the figures) to drive the light-emitting elements to emit light under the action of signals of drive signal lines such as scan signal lines 22 and data signal lines 23 on the array substrate.

As shown in FIG. 1, the multiple pixel driving circuits 20 may be arranged in an array. Optionally, each scan signal line 22 of multiple scan signal lines 22 is electrically connected to a corresponding row of pixel driving circuits 20 for sequentially applying a scan signal to each row of pixel driving circuits 20. Each data signal line 23 of multiple data signal lines 23 is electrically connected to a corresponding column of pixel driving circuits 20 for applying a data signal to the pixel driving circuits 20.

In other embodiments, the multiple pixel driving circuits 20 may also use other arrangement manners according to actual requirements. This is not limited in this embodiment of the present application.

With continued reference to FIGS. 1 to 3, each pixel driving circuit of the pixel driving circuits 20 includes the at least one transistor 11. Each transistor of the at least one transistor 11 includes the active layer 12, the first gate 14 and the first electrode 15. Exemplarily, when the array substrate is used for a liquid crystal display (LCD) panel, the each scan signal line 22 may be connected to the first gate 14 of the transistor 11, and the each data signal line 23 may be connected to the first electrode 15 of the transistor 11. The transistors 11 can be controlled to turn on through putting scan signal into the scan signal line 22. After input to the each data signal line 23, a data signal is transmitted to a pixel electrode 21 connected to the transistor 11 through the turned-on transistor 11 so that liquid crystal molecules in the liquid crystal display panel can be deflected. Moreover, the size of formed electric field and the degree of deflection of the liquid crystal molecules vary with the data signal change. The transmittance of the display panel varies with the degree of the deflection of the liquid crystal molecules, so that the amount of light generated by the backlight assembly and transmitting through the display panel also varies, causing different display brightness. Therefore, an image can be displayed.

For example, the material of the active layer 12 may use metal oxide. The metal oxide may be metal oxide composed of one or a combination of Zn, Ga, In, Sn, Al, Hf, C, B, N and S so that the transistor 11 can have the advantages of high carrier mobility, low deposition temperature and high transparency.

Exemplarily, the material of the active layer 12 may be indium gallium zinc oxide (IGZO). IGZO is an amorphous oxide containing indium, gallium and zinc, and the carrier mobility is relatively high. When the array substrate is used for the liquid crystal display panel, the active layer 12 using IGZO can improve the charge and discharge rates of the transistor 11 to the pixel electrode, increase the response speed of pixels and achieve a faster refresh rate.

In other embodiments, the material of the active layer 12 may also use another metal oxide such as indium zinc oxide (IZO), indium tin oxide (ITO) or indium tin zinc oxide (ITZO). This is not limited in this embodiment of the present application.

FIG. 4 is a diagram illustrating the structure of a transistor in the related art. As shown in FIG. 4, an IGZO transistor 11′ in the array substrate uses a bottom-gate type structure (also referred to as a back-channel type structure). The IGZO transistor 11′ includes an active layer 12′, a gate 14′ and a source-drain electrode layer 15′. The gate 14′ is located on a side of the active layer 12′ facing a substrate 10′. A gate insulating layer 16′ is included between the gate 14′ and the active layer 12′. The source-drain electrode layer 15′ is located on a side of the active layer 12′ facing away from the substrate 10′ and may be connected to a pixel electrode 21′.

Through research, the inventors have found that when the active layer 12′ is prepared on the gate insulating layer 16′, IGZO film formation needs to be performed through an ion sputtering process to form the active layer 12′. When the ion sputtering process is performed, due to relatively large ion bombardment energy, the surface of the gate insulating layer 16′ is damaged so that many defects can be formed at the interface between the active layer 12′ and the gate insulating layer 16′.

In this way, when the IGZO transistor 11′ is driven, a large number of electron capture phenomena are generated at the interface between the active layer 12′ and the gate insulating layer 16′ due to the many defects. As the duration of a voltage applied to the gate 14′ of the IGZO transistor 11′ progresses, a large number of electrons are captured in the interface between the active layer 12′ and the gate insulating layer 16′, causing great changes in a threshold voltage of the IGZO transistor 11′, and thereby resulting in a relatively poor stability of the IGZO transistor 11′.

In addition, the thickness of the gate 14′ of the IGZO transistor 11′ is about 300 nm. To ensure the insulation between the gate 14′ and the active layer 12′, the thickness of the gate insulating layer 16′ needs to be greater than the thickness of the gate 14′. For example, the thickness of the gate insulating layer 16′ is about 400 nm.

According to the formula:

$${I}_{D}^{′} = {μ}^{′} {C}_{ox}^{′} \frac{{W}^{′}}{{L}^{′}} ( {V}_{G}^{′} - {V}_{t h}^{′} ) {V}_{D}^{′} , {C}_{ox}^{′} = \frac{{ε}^{′}}{{h}^{′}}$$

It can be seen that the larger the thickness h′ of the gate insulating layer 16′, the smaller the capacitance Cₒₓ′ between the gate 14′ and the active layer 12′, so the smaller the on-state current I_{D}′ of the IGZO transistor 11′. The on-state current I_{D}′ of the IGZO transistor 11′ is relatively small, so a channel region of the active layer 12′ needs to have a relatively large aspect ratio W′/L′ to satisfy the drive requirements of a light-emitting element, resulting in a relatively large volume of the IGZO transistor 11′ and thereby it is unfavorable for improving the display resolution.

It is to be noted that in the preceding formula, μ′ denotes the carrier mobility of the IGZO transistor 11′, V_{G}′ denotes the voltage of the gate of the IGZO transistor 11′, Vₜₕ′ denotes the threshold voltage of the IGZO transistor 11′, V_{D}′ denotes the voltage of the drain of the IGZO transistor 11′, and E′ denotes a dielectric constant of the gate insulating layer 16′.

Based on the preceding technical problems, with continued reference to FIGS. 1 to 3, in this embodiment of the present application, along the thickness direction of the substrate 10, the first electrode 15 and the first gate 14 of the transistor 11 are located on the side of the active layer 12 facing away from the substrate 10. That is, the transistor 11 uses a top gate structure. A first gate insulating layer 16 is included between the first gate 14 and the active layer 12.

According to the preceding technical solution adopted, when the first gate insulating layer 16 is prepared on the side of the active layer 12 facing away from the substrate 10, chemical reaction film formation may be performed through chemical vapor deposition (CVD) to form the first gate insulating layer 16. The film formation mode has relatively few defects formed between the first gate insulating layer 16 and the active layer 12. Therefore, when the transistor 11 is driven, the electron capture phenomena at the interface between the first gate insulating layer 16 and the active layer 12 can be reduced, and as the duration of a voltage applied to the first gate 14 progresses, the electrons captured at the interface between the first gate insulating layer 16 and the active layer 12 are reduced so that threshold voltage drift phenomena of the transistor 11 can be improved, improving the stability of the transistor 11.

Moreover, due to the relatively small thickness of the active layer 12, the first gate insulating layer 16 may be provided with a relatively small thickness. For example, the thickness of the first gate insulating layer 16 may be 50 nm to 300 nm.

According to the formula:

$${I}_{D} = μ {C}_{ox} \frac{W}{L} ( {V}_{G} - {V}_{th} ) {V}_{D} , {C}_{ox} = \frac{ε}{h}$$

It can be seen that the thickness h of the first gate insulating layer 16 is relatively small, so the capacitance Cₒₓ between the first gate 14 and the active layer 12 may be increased so that the on-state current I_{D} of the transistor 11 can also be increased to satisfy the drive requirements of the light-emitting element with a relatively small aspect ratio W/L, thereby reducing the volume of the transistor 11 and helping improve the display resolution.

It is to be noted that in the preceding formula, p denotes the carrier mobility of the transistor 11, V_{G} denotes the voltage of the gate of the transistor 11, Vₜₕ denotes the threshold voltage of the transistor 11, V_{D} denotes the voltage of the drain of the transistor 11, and ε denotes a dielectric constant of the first gate insulating layer 16.

With continued reference to FIGS. 1 to 3, the active layer 12 includes the channel region 121, the vertical projection of the first gate 14 on the active layer 12 at least partially overlaps the channel region 121, and the first electrode 15 is electrically connected to the region of the active layer 12 other than the channel region 121.

When the transistor 11 is prepared, conductive processing is performed on the region of the active layer 12 other than the channel region 121 so that the conductive capability of the active layer 12 in the region other than the channel region 121 can be greater than the conductive capability of the active layer 12 in the channel region 121, thereby improving the electrical connection performance between the active layer 12 and the first electrode 15.

Along the thickness direction of the substrate 10, the channel region 121 may be a region overlapping the first gate 14. That is, the vertical projection of the channel region 121 on the active layer 12 coincides with the channel region 121.

Optionally, in the preparation process of the transistor 11, after the active layer 12 and the first gate 14 are formed, the first gate 14 may be used as a blocking layer, and ion implantation is performed on the active layer 12 through a doping process so that doped ions can be implanted into the active layer 12 in the form of an ion beam. After a controllable number of doped ions are doped to the active layer 12, the electrical performance of the active layer 12 is changed so that the active layer 12 can be conductive. When ion implantation is performed on the active layer 12, along the thickness direction of the substrate 10, the doped ions cannot be implanted into the active layer 12 because the channel region 121 of the active layer 12 is blocked by the first gate 14, while ions can be implanted into a partial region of the active layer 12 not blocked by the first gate 14 so that the conductivity of this partial region can be improved.

It is to be noted that the mode of performing ion implantation on the active layer 12 using the first gate 14 as the blocking layer can omit a process of a mask so that the preparation process of the transistor 11 can be simplified.

It is to be noted that when ion implantation is performed on the active layer 12, the doped ions may include boron ions, phosphorus ions, hydrogen ions, or argon ions so that the active layer 12 can have a good conductivity in the region subjected to ion implantation. However, this is not limited here.

With continued reference to FIGS. 1 to 3, the inventors have found through research that when ion implantation is performed on the active layer 12, the first electrode 15 also blocks the active layer 12 so that the doped ions cannot be implanted into the region of the active layer 12 covered by the first electrode 15. Therefore, the active layer 12 under the first electrode 15 cannot be conductive through a doping process. In this case, a relatively large resistance exists between the active layer 12 and the first electrode 15 so that the current transmission in the active layer 12 can become more difficult, thereby reducing the on-state current of the transistor 11.

Based on the preceding technical problems, as shown in FIGS. 1 to 3, in this embodiment, the active layer 12 further includes the first ohmic contact region 122. The first ohmic contact layer 13 is disposed between the active layer 12 and the first electrode 15, and the first ohmic contact layer 13 is in contact connection with the active layer 12 in the first ohmic contact region 122, or a region in which the active layer 12 and the first ohmic contact layer 13 are in contact connection is the first ohmic contact region 122.

The ohmic contact is formed between the surface of the active layer 12 and the first ohmic contact layer 13 through the atomic diffusion in the first ohmic contact layer 13 using the alloy penetration and diffusion technologies so that the active layer 12 can be conductive in the first ohmic contact region 122, thereby solving the problem that a region of the active layer 12 overlapping the first electrode 15 cannot be conductive through a doping process due to the blocking of ion implantation by the first electrode 15.

For example, the first electrode 15 is electrically connected to the first ohmic contact layer 13 so that the first electrode 15 can be electrically connected to the active layer 12 through the first ohmic contact layer 13, thereby improving the electrical connection performance between the first electrode 15 and the active layer 12 and reducing the resistance between the first electrode 15 and the active layer 12, and so that the current transmission in the active layer 12 can be easier, thereby increasing the on-state current of the transistor 11.

Optionally, the material of the first ohmic contact layer 13 includes at least one of molybdenum (Mo), niobium (Nb), or titanium (Ti), that is, the material of the ohmic contact layer 13 may be any one of the preceding materials or an alloy of any two or more of the preceding materials such as an MoNb alloy. The preceding materials are easy to diffuse atoms into the active layer 12, thereby helping make the active layer 12 conductive in the first ohmic contact region 122. Meanwhile, the preceding materials also have good conductivity, further helping reduce the connection resistance between the first electrode 15 and the active layer 12 and increasing the on-state current of the transistor 11. However, this is not limited here.

Optionally, with continued reference to FIG. 3, the thickness of the first ohmic contact layer 13 is h1, where 0<h1≤150 nm. The thickness h1 of the first ohmic contact layer 13 is less than or equal to 150 nm so that the lighter and thinner design of the array substrate can be facilitated while the process difficulty of preparing the first ohmic contact layer 13 can be reduced. However, this is not limited here.

Optionally, the material of the first gate 14 includes at least one of copper (Cu), aluminum (Al), molybdenum (Mo), gold (Au), niobium (Nb), or titanium (Ti), that is, the material of the first gate 14 may be any one of the preceding materials or an alloy of any two or more of the preceding materials to achieve a good conductivity. However, this is not limited here.

With continued reference to FIG. 3, optionally, the thickness of the first gate 14 is h2, where 0<h2≤400 nm. The thickness h2 of the first gate 14 is less than or equal to 400 nm so that the lighter and thinner design of the array substrate can be facilitated while the process difficulty of preparing the first gate 14 can be reduced. However, this is not limited here.

Optionally, the material of the first electrode 15 includes at least one of copper (Cu), aluminum (Al), molybdenum (Mo), gold (Au), niobium (Nb), or titanium (Ti), that is, the material of the first electrode 15 may be any one of the preceding materials or an alloy of any two or more of the preceding materials to achieve a good conductivity. However, this is not limited here.

Optionally, with continued reference to FIG. 3, the thickness of the first electrode 15 is h3, where 0<h3≤400 nm. The thickness h3 of the first electrode 15 is less than or equal to 400 nm so that the lighter and thinner design of the array substrate can be facilitated while the process difficulty of preparing the first electrode 15 can be reduced. However, this is not limited here.

In conclusion, in the array substrate according to this embodiment of the present application, the at least one transistor whose active layer material is metal oxide uses a top gate structure so that the first gate insulating layer can be formed through chemical reaction film formation to form relatively few defects between the first gate insulating layer and the active layer, thereby reducing the electron capture phenomenon at the interface between the first gate insulating layer and the active layer, reducing the threshold voltage drift of the at least one transistor and improving the stability of the at least one transistor. Moreover, the first gate insulating layer can be provided with a relatively small thickness to increase the capacitance between the first gate and the active layer so that the on-state current of the at least one transistor can be increased, thereby satisfying the drive requirements of the light-emitting element with a relatively small aspect ratio and helping improve the display resolution. For example, the first ohmic contact layer is disposed between the active layer and the first electrode so that the first electrode can be in contact connection with the first ohmic contact region of the active layer through the first ohmic contact layer to form the ohmic contact between the surface of the active layer and the first ohmic contact layer through the atomic diffusion in the first ohmic contact layer using the alloy penetration and diffusion technologies. In this way, the active layer can be conductive in the first ohmic contact region, the problem that the region of the active layer overlapping the first electrode cannot be conductive through a doping process due to the blocking of ion implantation by the first electrode can be solved, the electrical connection performance between the first electrode and the active layer can be improved, and the resistance between the first electrode and the active layer can be reduced so that the current transmission in the active layer can be easier, and the on-state current of the at least one transistor can be increased.

With continued reference to FIGS. 1 to 3, optionally, along the first direction X, the distance from the boundary of a side of the first ohmic contact layer 13 close to the channel region 121 to the channel region 121 is d1, and the distance from the boundary of a side of the first electrode 15 close to the channel region 121 to the channel region 121 is d2, where d1≤d2, and the first direction X is the direction of the first ohmic contact region 122 pointing to the channel region 121.

Exemplarily, as shown in FIG. 3, with the configuration of d1≤d2, the right boundary of the first ohmic contact layer 13 (that is, the boundary of the side of the first ohmic contact layer 13 close to the channel region 121) can be located on a side of the right boundary of the first electrode 15 (that is, the boundary of the side of the first electrode 15 close to the channel region 121) close to the channel region 121 so that the vertical projection of the boundary of the side of the first electrode 15 close to the channel region 121 on the active layer 12 is within the vertical projection of the first ohmic contact layer 13 on the active layer 12. With such a configuration, along the first direction X, from the position at which the first electrode 15 and the first ohmic contact layer 13 are connected to the boundary position of the side of the first electrode 15 close to the channel region 121, the region in which the active layer 12 is blocked by the first electrode 15 can be conductive through the atomic diffusion in the first ohmic contact layer 13 so that the active layer 12 between the position at which the first electrode 15 and the first ohmic contact layer 13 are connected and the boundary position of the channel region 121 can be conductive, further reducing the resistance between the first electrode 15 and the channel region 121 of the active layer 12, and so that the current transmission in the active layer 12 can be easier, thereby increasing the on-state current of the transistor 11.

It is to be noted that along the first direction X, the relative positional relationship between the boundary of the side of the first ohmic contact layer 13 away from the channel region 121 and the boundary of the side of the active layer 12 away from the channel region 121 is not limited in this embodiment. It is to be understood that along the first direction X, conductive processing is not performed on the active layer 12 located on a side of the position, at which the first electrode 15 and the first ohmic contact layer 13 are connected, away from the channel region 121, which will not greatly affect the performances of the transistor 11.

With continued reference to FIG. 3, optionally, the first gate 14 and the first electrode 15 are located in the same layer.

The first gate 14 and the first electrode 15 are located in the same layer so that one metal layer can be reduced, thereby reducing the production cost and the thickness of the substrate. Moreover, the first gate 14 and the first electrode 15 may use the same material so that the first gate 14 and the first electrode 15 can be prepared in the same process, thereby shortening the process time.

In other embodiments, along the thickness direction of the substrate 10, the first electrode 15 may also be located on a side of the first gate 14 close to the substrate 10. This is not limited in this embodiment of the present application.

With continued reference to FIGS. 1 to 3, optionally, the array substrate according to this embodiment of the present application further includes the first gate insulating layer 16, and along the thickness direction of the substrate 10, the first gate insulating layer 16 is located between the first electrode 15 and the active layer 12, and the first ohmic contact layer 13 is located between the first gate insulating layer 16 and the active layer 12, and the vertical projection of the first ohmic contact layer 13 on the active layer 12 coincides with the first ohmic contact region 122.

In an embodiment, as shown in FIG. 3, the first gate insulating layer 16 is disposed between the first electrode 15 and the active layer 12 so that the first gate insulating layer 16 can ensure the insulation between the first gate 14 and the active layer 12 when the first electrode 15 and the first gate 14 are disposed in the same layer.

The first ohmic contact layer 13 is a film adjacent to the active layer 12, and the region in which the first ohmic contact layer 13 is in contact with the active layer 12 is the first ohmic contact region 122. With such a configuration, when the active layer 12 and the first ohmic contact layer 13 are prepared, an entire active material layer and an entire first ohmic contact material layer can be sequentially prepared on the side of the substrate 10, and then a halftone mask (HTM) can be used for performing operations such as exposure on the active material layer and the first ohmic contact material layer in the same process to etch the active material layer and the first ohmic contact material layer so that the active layer 12 and the first ohmic contact layer 13 can be formed in the same process, shortening the process time.

With continued reference to FIGS. 2 and 3, optionally, the first gate insulating layer 16 may be provided with a connection via 161 through which the first electrode 15 may be electrically connected to the first ohmic contact layer 13. However, this is not limited here.

With continued reference to FIGS. 2 and 3, optionally, along the first direction X, the distance from the boundary of the side of the first ohmic contact layer 13 facing away from the channel region 121 to the channel region 121 is d3, and the distance from the boundary of a side of the connection via 161 facing away from the channel region 121 to the channel region 121 is d4, where d3≥d4.

With the configuration of d3≥d4, the left boundary of the first ohmic contact layer 13 (that is, the boundary of the side of the first ohmic contact layer 13 away from the channel region 121) can be located on a side of the left boundary of the connection via 161 (that is, the boundary of the side of the connection via 161 away from the channel region 121) away from the channel region 121 so that the vertical projection of the boundary of the side of the connection via 161 away from the channel region 121 on the active layer 12 can be within the vertical projection of the first ohmic contact layer 13 on the active layer 12. With such a configuration, along the thickness direction of the substrate, the first ohmic contact layer 13 can cover the entire connection via 161 so that the contact connection area between the first electrode 15 and the first ohmic contact layer 13 can be maximized, and the connection resistance between the first electrode 15 and the first ohmic contact layer 13 can be reduced.

With continued reference to FIG. 3, optionally, the thickness of the first gate insulating layer 16 is h, where 50 nm≤h≤300 nm.

As described in the preceding, the thickness h of the first gate insulating layer 16 satisfies 50 nm≤h≤300 nm so that the first gate insulating layer 16 can have a relatively small thickness, thereby increasing the capacitance between the first gate 14 and the active layer 12, helping increase the on-state current of the transistor 11 and satisfying the drive requirements of the light-emitting element with a relatively small channel aspect ratio (i.e., width to length ratio).

Optionally, the material of the first gate insulating layer 16 includes silicon oxide. The first gate insulating layer 16 uses the silicon oxide material so that the active layer 12 can be prevented from being conductive due to the diffusion of atoms in the first gate insulating layer 16 into the active layer 12 when the first gate insulating layer 16 is in contact with the active layer 12, thereby avoiding affecting the performance of the channel region 121 due to the channel region 121 of the active layer 12 being conductive.

FIG. 5 is a diagram illustrating the partial structure of an array substrate according to embodiments of the present application. FIG. 6 is a sectional diagram taken along a direction C-C′ of FIG. 5. As shown in FIGS. 5 and 6, optionally, the first ohmic contact region 122 abuts onto the channel region 121.

In an embodiment, as shown in FIGS. 5 and 6, along the first direction X, the boundary of a side of the first ohmic contact region 122 close to the channel region 121 at least partially coincides with the boundary of a side of the channel region 121 close to the first ohmic contact region 122 so that the first ohmic contact region 122 can communicate with the channel region 121. With such a configuration, when the first ohmic contact region 122 of the active layer 12 is conductive through the atomic diffusion of the first ohmic contact layer 13, and the transistor 11 is turned on, a current may be directly transmitted to the channel region 121 through the first electrode 15, the first ohmic contact layer 13 and the first ohmic contact region 122 of the active layer 12 sequentially, and no region that is not conductive exists between the first ohmic contact region 122 and the channel region 121 of the active layer 12. Therefore, there is no need to conduct the region between the first ohmic contact region 122 and the channel region 121 of the active layer 12 through a doping process to reduce the connection resistance between the first electrode 15 and the active layer 12 so that the transistor 11 can be ensured to have a relatively large on-state current while the process time can be shortened.

With continued reference to FIGS. 2 and 3, optionally, the active layer 12 further includes a first doping region 123 abutting onto the first ohmic contact region 122 and the channel region 121.

As shown in FIGS. 2 and 3, the active layer 12 is further provided with the first doping region 123 between the first ohmic contact region 122 and the channel region 121, and along the first direction X, the boundary of a side of the first ohmic contact region 122 close to the first doping region 123 at least partially coincides with the boundary of a side of the first doping region 123 close to the first ohmic contact region 122 so that the first ohmic contact region 122 can communicate with the first doping region 123; and the boundary of a side of the first doping region 123 close to the channel region 121 at least partially coincides with the boundary of a side of the channel region 121 close to the first doping region 123 so that the first doping region 123 can communicate with the channel region 121.

With such a configuration, the first ohmic contact region 122 of the active layer 12 can be conductive through the atomic diffusion of the first ohmic contact layer 13. The first doping region 123 may be conductive through ion implantation performed on the first doping region 123 of the active layer 12 through a doping process. When the transistor 11 is turned on, a current may be transmitted to the channel region 121 sequentially through the first electrode 15, the first ohmic contact layer 13, the first ohmic contact region 122 of the active layer 12 and the first doping region 123 of the active layer 12.

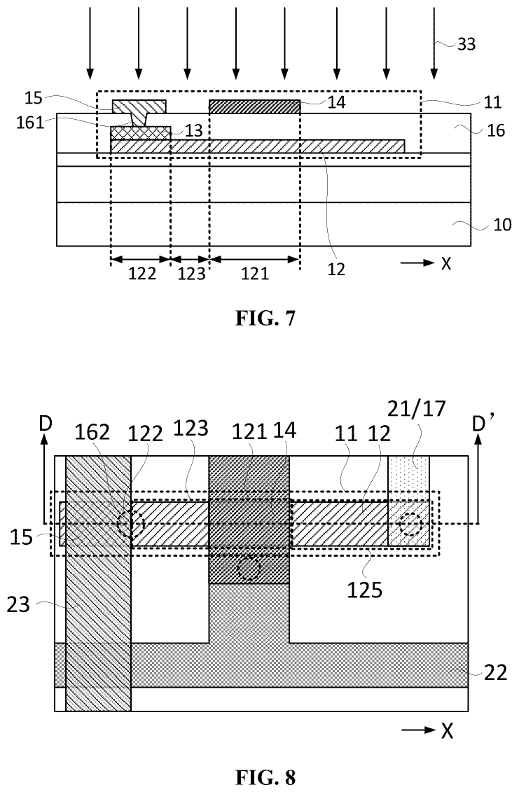

FIG. 7 is a diagram illustrating a preparation method for a transistor according to embodiments of the present application. As shown in FIG. 7, when ion implantation is performed on the first doping region 123, an ion beam 33 is emitted to the entire surface of the transistor 11, and the first gate 14 may be used as the blocking layer so that doped ions cannot be implanted into the region of the active layer 12 blocked by the first gate 14, thereby forming the channel region 121, and so that the doped ions can be implanted into the region of the active layer 12 not blocked by the first gate 14, the first electrode 15 and the first ohmic contact layer 13 to conduct the region, thereby forming the first doping region 123. With such a configuration, along the first direction X, the boundary between the conducted region of the active layer 12 and the channel region 121, that is, the boundary between the first doping region 123 and the channel region 121, just coincides with the vertical projection of the boundary of the first gate 14 on the active layer 12 so that the actual length of the channel region 121 can be avoided to be affected due to the overlapping between the conducted region of the active layer 12 and the first gate 14 caused by a process error, and so that the resistance between the active layer 12 and the first electrode 15 can be prevented from increasing due to a gap between the conducted region of the active layer 12 and the channel region 121 caused by a process error, and the on-state current of the transistor 11 can be ensured to satisfy the drive requirements of the light-emitting element.

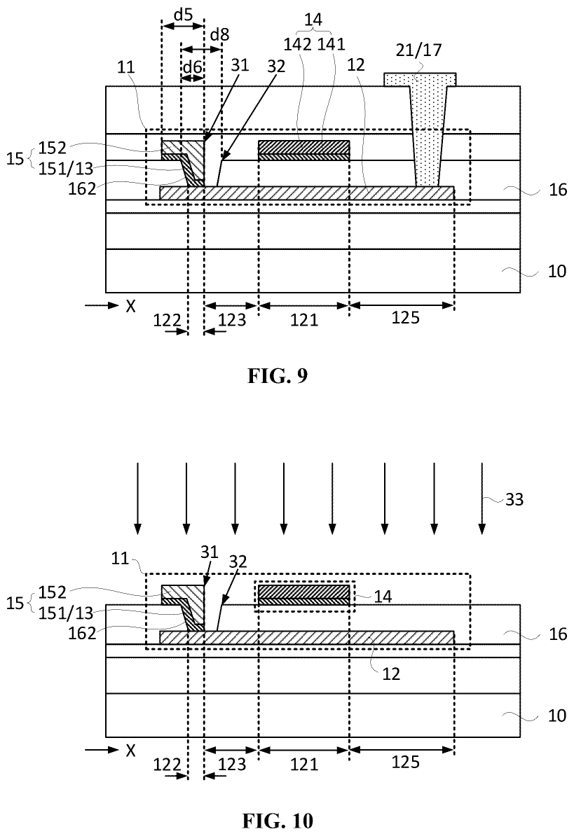

FIG. 8 is a diagram illustrating the partial structure of another array substrate according to embodiments of the present application. FIG. 9 is a sectional diagram taken along a direction D-D′ of FIG. 8. As shown in FIGS. 8 and 9, optionally, the array substrate according to this embodiment of the present application further includes the first gate insulating layer 16, and along the thickness direction of the substrate 10, the first gate insulating layer 16 is located between the first electrode 15 and the active layer 12, and the first ohmic contact layer 13 is located between the first gate insulating layer 16 and the first electrode 15. The first gate insulating layer 16 is provided with a first via 162 through which the first ohmic contact layer 13 is in contact connection with the active layer 12. Along the first direction X, a first boundary 31 of the first electrode 15 is located on a side of a second boundary 32 of the first via 162 away from the channel region 121. The first boundary 31 is the boundary of a side of the first electrode 15 close to the channel region 121, the second boundary 32 is the boundary of a side of the first via 162 close to the channel region 121, and the first direction X is the direction of the first ohmic contact region 122 pointing to the channel region 121.

In an embodiment, as shown in FIGS. 8 and 9, the first gate insulating layer 16 is disposed between the first electrode 15 and the active layer 12 so that the first gate insulating layer 16 can ensure the insulation between the first gate 14 and the active layer 12 when the first electrode 15 and the first gate 14 are disposed in the same layer.

The first ohmic contact layer 13 is a film adjacent to the first electrode 15, and the first ohmic contact layer 13 is in direct contact connection with the first electrode 15. The first gate insulating layer 16 is provided with the first via 162 through which the first ohmic contact layer 13 overlaps the active layer 12. The region in which the first ohmic contact layer 13 is in contact with the active layer 12 is the first ohmic contact region 122.

Along the thickness direction of the substrate 10, the vertical projection of the first ohmic contact layer 13 on the substrate 10 may coincide with the vertical projection of the first electrode 15 on the substrate 10. In this way, when the first ohmic contact layer 13 and the first electrode 15 are prepared, an entire first ohmic contact material layer and an entire first electrode material layer can be sequentially prepared on the side of the substrate 10 and are etched in the same process to form the first ohmic contact layer 13 and the first electrode 15 in the same process so that the process time can be shortened.

With continued reference to FIG. 9, along the direction of the first ohmic contact region 122 pointing to the channel region 121 (such as the first direction X), the first boundary 31 of the side of the first electrode 15 close to the channel region 121 is located on the side of the second boundary 32 away from the channel region 121, where the second boundary 32 is on the side of the first via 162 close to the channel region 121. In this case, along the thickness direction of the substrate 10, the first via 162 has a region that does not overlap the first electrode 15, that is, the first electrode 15 does not cover the entire first via 162, and the region in which the first via 162 and the first electrode 15 do not overlap is located on the side of the first electrode 15 close to the channel region 121.

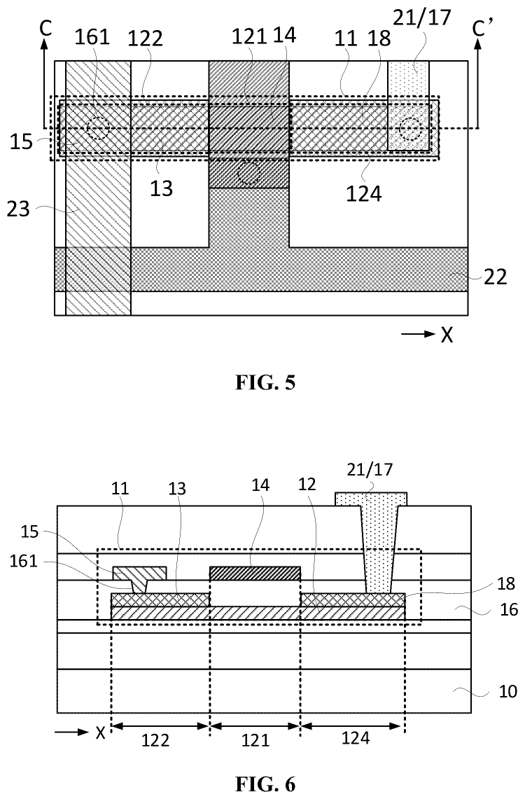

FIG. 10 is a diagram illustrating a preparation method for a transistor according to embodiments of the present application. As shown in FIG. 10, when ion implantation is performed on the active layer 12 through a doping process, an ion beam 33 is emitted to the entire surface of the transistor 11, and the first gate 14 is used as the blocking layer so that doped ions cannot be implanted into the region of the active layer 12 blocked by the first gate 14, thereby forming the channel region 121. In this case, the first electrode 15 does not block the region between the first ohmic contact region 122 and the channel region 121 of the active layer 12 so that the entire region between the first ohmic contact region 122 and the channel region 121 can be conductive, helping reduce the connection resistance between the first electrode 15 and the active layer 12, and so that the current transmission in the active layer 12 can be easier, thereby increasing the on-state current of the transistor 11.

As shown in FIGS. 8 and 9, along the thickness direction of the substrate 10, since the boundary of the side of the first electrode 15 close to the channel region 121 needs to overlap the first via 162, the diameter of the first via 162 may be greater than or equal to 2 μm to reduce the difficulties of preparing the first via 162 and the first electrode 15.

With continued reference to FIG. 9, optionally, the length of the first electrode 15 in the first direction X is d5, and along the thickness direction of the substrate 10, the length of an overlapping region between the first electrode 15 and the first via 162 in the first direction X is d6, where d6≥(½)*d5.

As shown in FIG. 9, the length d6 of the overlapping region between the first electrode 15 and the first via 162 in the first direction X and the length d5 of the first electrode 15 in the first direction X satisfy d6≥(½)*d5 to ensure that the first electrode 15 and the first via 162 can each have a relatively large overlapping area. When the first electrode 15 is electrically connected to the active layer 12 exposed by the first via 162 through the first ohmic contact region 13, the connection resistance between the first electrode 15 and the active layer 12 can be reduced so that the current transmission in the active layer 12 can be easier, helping increase the response speed of the transistor 11 when the transistor 11 is turned on.

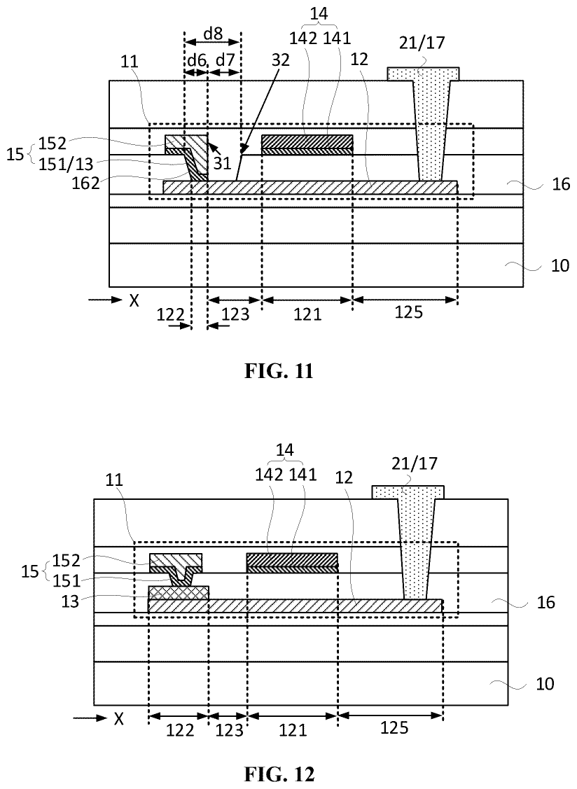

FIG. 11 is a diagram illustrating the partial cross section structure of an array substrate according to embodiments of the present application. As shown in FIG. 11, optionally, along the thickness direction of the substrate 10, the length of the overlapping region between the first electrode 15 and the first via 162 in the first direction X is d6, and along the thickness direction of the substrate 10, within the region in which the first via 162 is located, the length in the first direction X of the region other than the overlapping region between the first via 162 and the first electrode 15 is d7, where d7≥d6.

As shown in FIG. 11, along the thickness direction of the substrate 10, d7≥d6 is satisfied between the length d7 in the first direction X of the region of the first via 162 not covered by the first electrode 15 and the length d6 in the first direction X of the region of the first via 162 covered by the first electrode 15 so that the distance from the first boundary 31 of the first electrode 15 to the second boundary 32 of the first via 162 in the first direction X can be relatively long. With such a configuration, when the first electrode 15 is prepared, the position of the first boundary 31 of the first electrode 15 can be more easily controlled to be on the side of the second boundary 32 of the first via 162 away from the channel region 121 so that the process difficulty can be reduced, thereby preventing the first boundary 31 of the first electrode 15 from being finally located on the side of the second boundary 32 of the first via 162 close to the channel region 121 due to a process error, and further preventing the first electrode 15 from blocking the region between the first ohmic contact region 122 and the channel region 121 of the active layer 12 when ion implantation is performed on the active layer 12 through a doping process.

With continued reference to FIGS. 9 and 11, optionally, along the thickness direction of the substrate 10, the length of the overlapping region between the first electrode 15 and the first via 162 in the first direction X is d6, and the length in the first direction X of the region in which the first via 162 is located is d8, where 10%≤d6/d8≤90%.

As shown in FIGS. 9 and 11, 10%≤d6/d8≤90% is satisfied between the length d6 of the overlapping region between the first electrode 15 and the first via 162 in the first direction X and the length d8 in the first direction X of the region in which the first via 162 is located. Therefore, in the first direction X, the distance from the first boundary 31 of the first electrode 15 to the boundary of the side of the first via 162 away from the channel region 121 can be enough, and when the first electrode 15 is prepared, the electrical connection between the first electrode 15 and the active layer 12 can be prevented from being affected by that the first boundary 31 of the first electrode 15 is finally located on the side of the first via 162 away from the channel region 121 due to a process error. Meanwhile, the connection area between the first electrode 15, the first ohmic contact layer 13 and the active layer 12 can be enough so that the electrical connection performance between the first electrode 15 and the active layer 12 can be ensured. Moreover, in the first direction X, the distance from the first boundary 31 of the first electrode 15 to the second boundary 32 of the first via 162 can be enough, and when the first electrode 15 is prepared, the position of the first boundary 31 of the first electrode 15 can be easily controlled to be on the side of the second boundary 32 of the first via 162 away from the channel region 121 so that the process difficulty can be reduced, thereby preventing the first boundary 31 of the first electrode 15 from being finally located on the side of the second boundary 32 of the first via 162 close to the channel region 121 due to a process error, and further preventing the first electrode 15 from blocking the region between the first ohmic contact region 122 of the active layer 12 and the channel region 121 of the active layer 12 when ion implantation is performed on the active layer 12 through a doping process.

With continued reference to FIGS. 9 and 11, optionally, the array substrate according to this embodiment of the present application further includes the first gate insulating layer 16, and along the thickness direction of the substrate 10, the first gate insulating layer 16 is located between the first electrode 15 and the active layer 12. The first electrode 15 includes a first conductive base layer 151 and a first conductive electrode layer 152 that are stacked, and along the thickness direction of the substrate 10, the first conductive base layer 151 is located on a side of the first conductive electrode layer 152 close to the first gate insulating layer 16, and the first conductive base layer 151 is in contact connection with the first conductive electrode layer 152. The first ohmic contact layer 13 and the first conductive base layer 151 have the same film structure.

In an embodiment, as shown in FIGS. 9 and 11, the first gate insulating layer 16 is disposed between the first electrode 15 and the active layer 12 so that the first gate insulating layer 16 can ensure the insulation between the first gate 14 and the active layer 12 when the first electrode 15 and the first gate 14 are disposed in the same layer.

For example, the first electrode 15 includes the first conductive base layer 151 and the first conductive electrode layer 152 that are electrical connected to each other, and the first conductive base layer 151 and the first gate insulating layer 16 are located in adjacent layers and are in contact connection. The first conductive electrode layer 152 is located on a side of the first conductive base layer 151 away from the substrate 10, and the first conductive electrode layer 152 and the first conductive base layer 151 are located in adjacent layers and are in contact connection.

The first conductive electrode layer 152 may use a metal material having a relatively good conductivity such as copper to ensure that the first electrode 15 has a good conductivity so that the power consumption of the transistor 11 can be reduced.

Through research, the inventors have found that atoms in the first conductive electrode layer 152 are easy to diffuse into the first gate insulating layer 16, affecting the insulating effect of the first gate insulating layer 16, and moreover, the first gate insulating layer 16 is generally an inorganic film, so the adhesion between the first conductive electrode layer 152 and the first gate insulating layer 16 is relatively poor. If the first conductive electrode layer 152 is directly prepared on the surface of the first gate insulating layer 16, the film formation quality of the first conductive electrode layer 152 will be affected.

Based on the preceding technical problems, in this embodiment, the first conductive base layer 151 is disposed between the first conductive electrode layer 152 and the first gate insulating layer 16 to prevent the atoms in the first conductive electrode layer 152 from diffusing into the first gate insulating layer 16 so that the problem that a large number of the atoms in the first conductive electrode layer 152 diffuse into the first gate insulating layer 16 can be solved.

The hardness of the first conductive base layer 151 may be greater than the hardness of the first conductive electrode layer 152 to reduce the diffusion degree of the atoms in the first conductive base layer 151 into the first gate insulating layer 16.

In some embodiments, the adhesion between the first conductive base layer 151 and the first gate insulating layer 16 may also be greater than the adhesion between the first conductive electrode layer 152 and the first gate insulating layer 16. With such a configuration, the first conductive base layer 151 is prepared on the first gate insulating layer 16 so that the film quality of the first conductive base layer 151 can be improved.

Optionally, the material of the first conductive base layer 151 may include at least one of molybdenum (Mo), niobium (Nb), or titanium (Ti), that is, the material of the first conductive base layer 151 may be any one of the preceding materials or an alloy of any two or more of the preceding materials. However, this is not limited here.

Exemplarily, the material of the first conductive base layer 151 uses an MoNb alloy so that the first conductive base layer 151 can have a relatively large hardness to reduce the diffusion degree of the atoms in the first conductive base layer 151 into the first gate insulating layer 16, and so that a relatively good adhesion can be achieved between the first conductive base layer 151 and the first gate insulating layer 16, and thus it helps improve the film quality of the first conductive base layer 151 that the first conductive base layer 151 is prepared on the first gate insulating layer 16.

With continued reference to FIGS. 9 and 11, optionally, the vertical projection of the first conductive base layer 151 on the substrate 10 coincides with the vertical projection of the first conductive electrode layer 152 on the substrate 10. With such a configuration, when the first electrode 15 is prepared, an entire first conductive base material layer and an entire first conductive electrode material layer can be sequentially prepared on the side of the first gate insulating layer 16 away from the substrate 10 and are etched in the same process to form the first conductive base layer 151 and the first conductive electrode layer 152 in the same process so that the process time can be shortened.

It is to be noted that in any one of the preceding embodiments, the first electrode 15 may include the first conductive base layer 151 and the first conductive electrode layer 152 that are stacked to prevent the atoms in the first conductive electrode layer 152 from diffusing into the first gate insulating layer 16 and improve the film quality of the first electrode 15. Details are not repeated here.

Exemplarily, FIG. 12 is a diagram illustrating the partial cross section structure of another array substrate according to embodiments of the present application. As shown in FIG. 12, when the first ohmic contact layer 13 is located between the first gate insulating layer 16 and the active layer 12, the first electrode 15 may also include the first conductive base layer 151 and the first conductive electrode layer 152 that are stacked. However, this is not limited in this embodiment.

With continued reference to FIGS. 3, 5 and 6, it is to be understood that when the material of the first electrode 15 includes molybdenum (Mo), niobium (Nb), or titanium (Ti) or an alloy of the preceding materials (such as the MoNb alloy), atoms in the first electrode 15 are difficult to diffuse into the first gate insulating layer 16, and meanwhile, a relatively good adhesion may also be achieved between the first electrode 15 and the first gate insulating layer 16. In this case, the first electrode 15 may be only a single-layer structure without the need to prepare a multilayer structure, thereby reducing the production cost and the thickness of the substrate and helping shorten the process time.

With continued reference to FIGS. 9 and 11, the first ohmic contact layer 13 and the first conductive base layer 151 may have the same film structure. With such a configuration, one metal layer may be reduced, thereby reducing the production cost and the thickness of the substrate. Meanwhile, the first ohmic contact layer 13 and the first conductive base layer 151 are formed in the same process so that the process time can be shortened.

With continued reference to FIG. 12, in some embodiments, the first ohmic contact layer 13 and the first conductive base layer 151 may also have different film structures. The first conductive base layer 151 and the first ohmic contact layer 13 may be located in adjacent layers, the first conductive base layer 151 is located on the side of the first ohmic contact layer 13 facing away from the substrate 10, and the first electrode 15 may be in contact connection with the first ohmic contact layer 13 through the first conductive base layer 151. With such a configuration, the design flexibility of the first ohmic contact layer 13 and the first electrode 15 can be improved.

With continued reference to FIGS. 9, 11 and 12, optionally, the first gate 14 includes a second conductive base layer 141 and a second conductive electrode layer 142 that are stacked, and along the thickness direction of the substrate 10, the second conductive base layer 141 is located on a side of the second conductive electrode layer 142 close to the first gate insulating layer 16, and the second conductive base layer 141 is in contact connection with the second conductive electrode layer 142.

The second conductive base layer 141 and the first gate insulating layer 16 are located in adjacent layers and are in contact connection. The second conductive electrode layer 142 is located on a side of the second conductive base layer 141 away from the substrate 10, and the second conductive electrode layer 142 and the second conductive base layer 141 are located in adjacent layers and are in contact connection.

The second conductive electrode layer 142 may use a metal material having a relatively good conductivity such as copper to ensure that the first gate 14 has a good conductivity. In this case, atoms in the second conductive electrode layer 142 are easy to diffuse into the first gate insulating layer 16, affecting the insulating effect of the first gate insulating layer 16, and moreover, the first gate insulating layer 16 is generally an inorganic film, so the adhesion between the second conductive electrode layer 142 and the first gate insulating layer 16 is relatively poor. If the second conductive electrode layer 142 is directly prepared on the surface of the first gate insulating layer 16, the film formation quality of the second conductive electrode layer 142 is affected.

In this embodiment, the second conductive base layer 141 is disposed between the second conductive electrode layer 142 and the first gate insulating layer 16 to prevent the atoms in the second conductive electrode layer 142 from diffusing into the first gate insulating layer 16 so that the problem that a large number of the atoms in the second conductive electrode layer 142 diffuse into the first gate insulating layer 16 can be solved.

The hardness of the second conductive base layer 141 may be greater than the hardness of the second conductive electrode layer 142 to reduce the diffusion degree of the atoms in the second conductive electrode layer 142 into the first gate insulating layer 16.

In some embodiments, the adhesion between the second conductive base layer 141 and the first gate insulating layer 16 may also be greater than the adhesion between the second conductive electrode layer 142 and the first gate insulating layer 16. With such a configuration, when the second conductive base layer 141 is prepared on the first gate insulating layer 16, the film quality of the second conductive base layer 141 can be improved.

Optionally, the material of the second conductive base layer 141 may include at least one of molybdenum (Mo), niobium (Nb), or titanium (Ti), that is, the material of the second conductive base layer 141 may be any one of the preceding materials or an alloy of any two or more of the preceding materials. However, this is not limited here.

Exemplarily, the material of the second conductive base layer 141 uses the MoNb alloy so that the second conductive base layer 141 can have a relatively large hardness to reduce the diffusion degree of the atoms in the second conductive base layer 141 into the first gate insulating layer 16, and so that a relatively good adhesion can be achieved between the second conductive base layer 141 and the first gate insulating layer 16, thereby helping improve the film quality of the second conductive base layer 141 when the second conductive base layer 141 is prepared on the first gate insulating layer 16.

With continued reference to FIGS. 9 and 11, optionally, the vertical projection of the second conductive base layer 141 on the substrate 10 coincides with the vertical projection of the second conductive electrode layer 142 on the substrate 10. With such a configuration, when the first gate 14 is prepared, an entire second conductive base material layer and an entire second conductive electrode material layer can be sequentially prepared on the side of the first gate insulating layer 16 away from the substrate 10 and are etched in the same process to form the second conductive base layer 141 and the second conductive electrode layer 142 in the same process so that the process time can be shortened.

It is to be noted that in any one of the preceding embodiments, the first gate 14 may include the second conductive base layer 141 and the second conductive electrode layer 142 that are stacked to prevent the atoms in the second conductive electrode layer 142 from diffusing into the first gate insulating layer 16 and improve the film quality of the first gate 14. Details are not repeated here.

With continued reference to FIGS. 9 and 11, optionally, the first ohmic contact layer 13 and the second conductive base layer 141 are located in the same layer. In this way, one metal layer may be reduced, thereby reducing the production cost and the thickness of the substrate. Meanwhile, the first ohmic contact layer 13 and the second conductive base layer 141 may also be formed in the same process so that the process time can be shortened.

With continued reference to FIGS. 3, 5 and 6, it is to be understood that when the material of the first gate 14 includes molybdenum (Mo), niobium (Nb), or titanium (Ti) or an alloy of the preceding materials (such as the MoNb alloy), atoms in the first gate 14 are difficult to diffuse into the first gate insulating layer 16, and meanwhile, a relatively good adhesion may be achieved between the first gate 14 and the first gate insulating layer 16. In this case, the first gate 14 may be only a single-layer structure without the need to prepare a multilayer structure, thereby reducing the production cost and the thickness of the substrate and helping shorten the process time.

It is to be noted that the array substrate may include multiple transistors 11, and each transistor 11 may use the structure of the transistor 11 according to any one of the preceding embodiments. For example, in the array substrate, the first ohmic contact layer 13 of at least some of the transistors 11 may be located between the first gate insulating layer 16 and the active layer 12 (as shown in FIGS. 3, 6 and 12), and the first ohmic contact layer 13 of at least some of the transistors 11 may be located between the first gate insulating layer 16 and first electrode 15 (as shown in FIGS. 9 and 11). This is not limited in this embodiment of the present application.

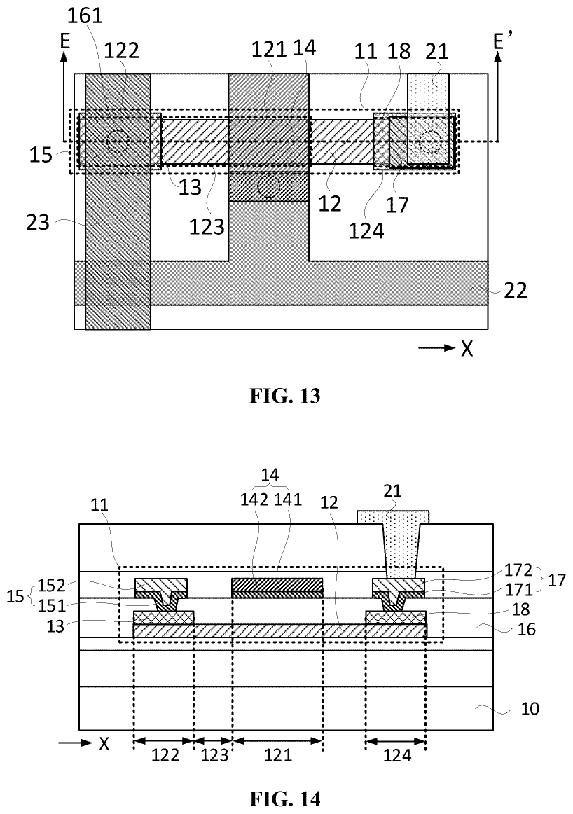

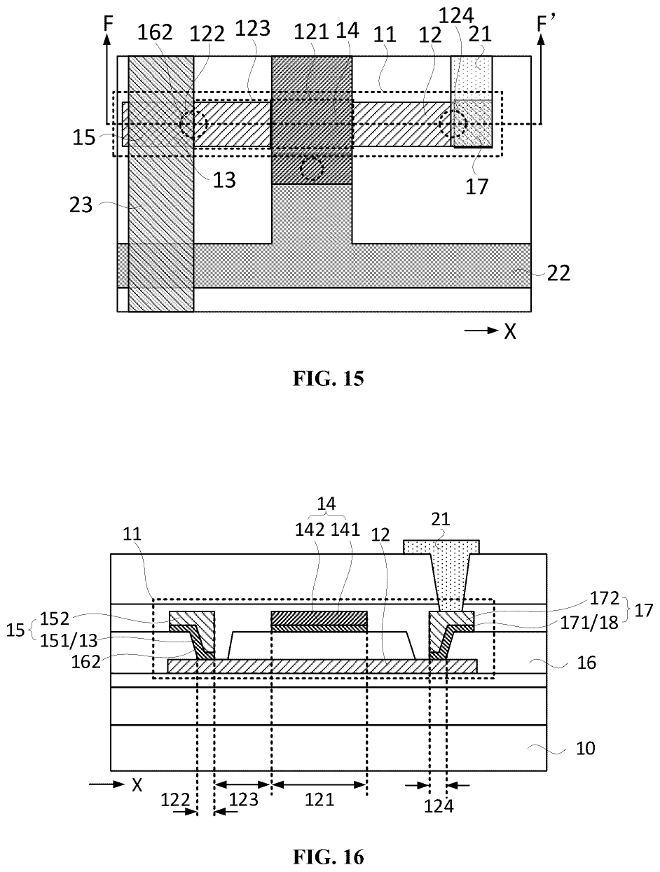

FIG. 13 is a diagram illustrating the partial structure of another array substrate according to embodiments of the present application. FIG. 14 is a sectional diagram taken along a direction E-E′ of FIG. 13. FIG. 15 is a diagram illustrating the partial structure of another array substrate according to embodiments of the present application. FIG. 16 is a sectional diagram taken along a direction F-F′ of FIG. 15. As shown in FIGS. 5 to 6 and 13 to 16, optionally, the transistor 11 further includes a second electrode 17 and a second ohmic contact layer 18. The second ohmic contact layer 18 is located on the side of the active layer 12 facing away from the substrate 10, and the second electrode 17 is located on a side of the second ohmic contact layer 18 facing away from the substrate 10. The active layer 12 further includes a second ohmic contact region 124 located on a side of the channel region 121 away from the first ohmic contact region 122. The second ohmic contact layer 18 is in contact connection with the second ohmic contact region 124 of the active layer 12. The second electrode 17 is electrically connected to the second ohmic contact layer 18.

In an embodiment, as shown in FIGS. 13 to 16, the transistor 11 further includes the second electrode 17. The first electrode 15 and the second electrode 17 may serve as the source and the drain of the transistor 11. For example, when the first electrode 15 serves as the source of the transistor 11, the second electrode 17 serves as the drain of the transistor 11, and when the first electrode 15 serves as the drain of the transistor 11, the second electrode 17 serves as the source of the transistor 11.

Optionally, the second electrode 17 and the first electrode 15 may be located in the same layer to reduce the number of metal layers, thereby reducing the production cost and the thickness of the substrate. Meanwhile, the second electrode 17 and the first electrode 15 may use the same material so that the second electrode 17 and the first electrode 15 can be prepared in the same process, thereby shortening the process time. However, this is not limited here.

It is to be noted that the second electrode 17 and the first electrode 15 may have the same structure, and the specific structure of the second electrode 17 may be referred to the specific structure of the first electrode 15 according to any one of the preceding embodiments. Details are not repeated here.

Exemplarily, as shown in FIGS. 13 to 16, the array substrate further includes the first gate insulating layer 16, and along the thickness direction of the substrate 10, the first gate insulating layer 16 is located between the first electrode 15 and the active layer 12. The second electrode 17 may include a third conductive base layer 171 and a third conductive electrode layer 172 that are stacked, and along the thickness direction of the substrate 10, the third conductive base layer 171 is located on a side of the third conductive electrode layer 172 close to the first gate insulating layer 16, and the third conductive base layer 171 is in contact connection with the third conductive electrode layer 172.

The structure of the third conductive base layer 171 may be disposed with reference to the structure of the first conductive base layer 151 in any one of the preceding embodiments. That is, the third conductive base layer 171 may use the same structure as the first conductive base layer 151 in any one of the preceding embodiments. The third conductive electrode layer 172 may be disposed with reference to the structure of the first conductive electrode layer 152 in any one of the preceding embodiments. That is, the third conductive electrode layer 172 may use the same structure as the first conductive electrode layer 152 in any one of the preceding embodiments. It is to be understood that the second electrode 17 includes the third conductive base layer 171 and the third conductive electrode layer 172 that are stacked so that atoms in the third conductive electrode layer 172 can be prevented from diffusing into the first gate insulating layer 16, and the film quality of the second electrode 17 can be improved. Details are not repeated here.

With continued reference to FIGS. 13 to 16, the active layer 12 further includes the second ohmic contact region 124, and the second ohmic contact layer 18 is disposed between the active layer 12 and the second electrode 17 and is in contact connection with the active layer 12 in the second ohmic contact region 124, or the region of the active layer 12 which is in contact connection with the second ohmic contact layer 18 is the second ohmic contact region 124.

The specific structure of the second ohmic contact layer 18 may be disposed with reference to the structure of the first ohmic contact layer 13 in any one of the preceding embodiments. That is, the second ohmic contact layer 18 may use the same structure as the first ohmic contact layer 13 in any one of the preceding embodiments. Details are not repeated here.

It is to be understood that ohmic contact is formed between the surface of the active layer 12 and the second ohmic contact layer 18 through atomic diffusion in the second ohmic contact layer 18 using the alloy penetration and diffusion technologies so that the active layer 12 can be conductive in the second ohmic contact region 124, thereby solving the problem that a region of the active layer 12 overlapping the second electrode 17 cannot be conductive through a doping process due to blocking of ion implantation by the second electrode 17.

With continued reference to FIGS. 13 to 16, optionally, the second electrode 17 may be electrically connected to the pixel electrode 21 in order to be connected to the light-emitting element through the pixel electrode 21, thereby driving the light-emitting element.

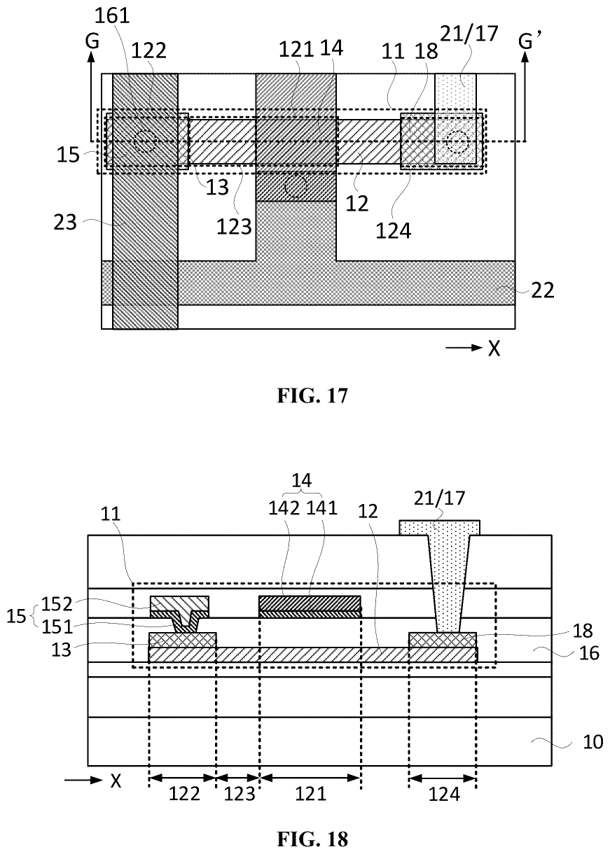

FIG. 17 is a diagram illustrating the partial structure of another array substrate according to embodiments of the present application. FIG. 18 is a sectional diagram taken along a direction G-G′ of FIG. 17. As shown in FIGS. 5, 6, 17 and 18, optionally, the second electrode 17 and the pixel electrode 21 are the same film structure. With such a configuration, one film layer can be reduced, thereby reducing the production cost and the thickness of the substrate. Meanwhile, the second electrode 17 and the pixel electrode 21 are formed in the same process so that the process time can be shortened.

With continued reference to FIGS. 1 to 3, 8 to 9 and 11 to 12, optionally, the transistor 11 further includes the second electrode 17, and along the thickness direction of the substrate 10, the second electrode 17 is located on the side of the first gate 14 facing away from the substrate 10. The active layer 12 further includes a second doping region 125 located on the side of the channel region 121 away from the first ohmic contact region 122. The second electrode 17 is in contact connection with the active layer 12 in the second doping region 125.

In an embodiment, as shown in FIGS. 1 to 3, 8 to 9 and 11 to 12, since the second electrode 17 is located on the side of the first gate 14 facing away from the substrate 10, and when the transistor 11 is prepared, the second electrode 17 is prepared after the preparation of the first gate 14 is completed, ion implantation may be performed on the active layer 12 through a doping process after the preparation of the first gate 14 is completed and before the second electrode 17 is prepared. In this case, the second electrode 17 has not been prepared, and an ion beam is not blocked by the second electrode 17 so that doped ions can be implanted into the second doping region 125 of the active layer 12, thereby conducting the second doping region 125.

For example, the second electrode 17 is in contact connection with the active layer 12 in the second doping region 125 to electrically connect the second electrode 17 to the active layer 12.

It is to be noted that when ion implantation is performed on the active layer 12 through a doping process, the first gate 14 is used as the blocking layer, and the finally formed second doping region 125 abuts onto the channel region 121, so ohmic contact for electrical connection does not need to be prepared between the second electrode 17 and the active layer 12 so that the number of metal layers can be reduced, reducing the production cost and the thickness of the substrate.

Optionally, the second electrode 17 is a transparent electrode.

The second electrode 17 is a transparent electrode so that a blocking area of light by the transistor 11 can be reduced, helping improve the aperture ratio.

For example, the material of the second electrode 17 may include any one or more of indium tin oxide (ITO), indium zinc oxide (IZO), antimony tin oxide (ATO), aluminum zinc oxide (AZO), or zinc oxide (ZnO) to have a good conductivity while the transmittance is ensured.

It is to be noted that the array substrate may include the multiple transistors 11, and the each transistor 11 may use the structure of the transistor 11 according to any one of the preceding embodiments. For example, in the array substrate, the second electrode 17 of at least some of the transistors 11 may be in contact connection with the second ohmic contact region 124 of the active layer 12 through the second ohmic contact layer 18 (as shown in FIGS. 5 to 6 and 13 to 18), and the second electrode 17 of at least some of the transistors 11 may be in direct contact connection with the second doping region 125 of the active layer 12 (as shown in FIGS. 1 to 3, 8 to 9 and 11 to 12). This is not limited in this embodiment of the present application.

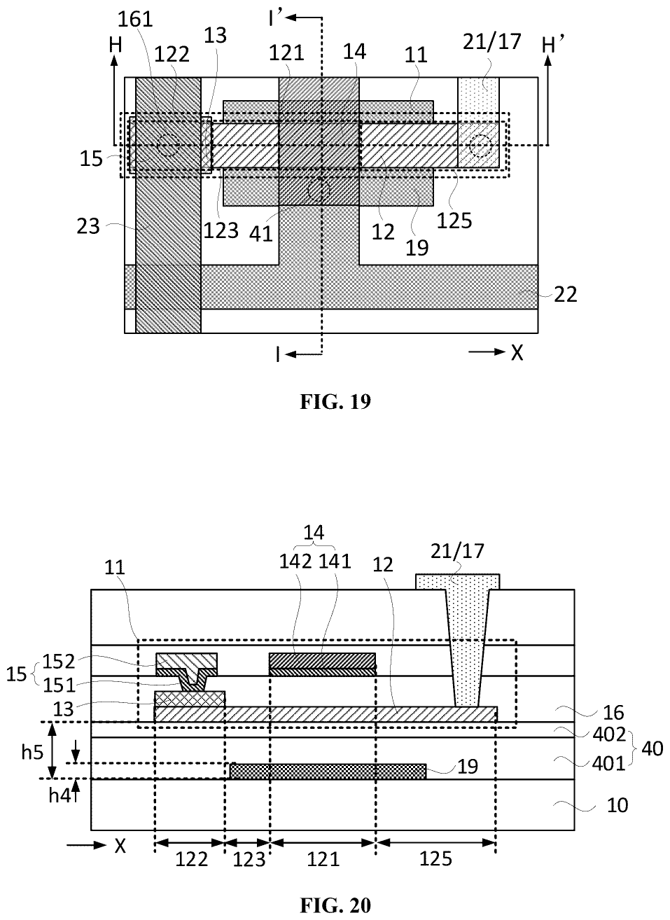

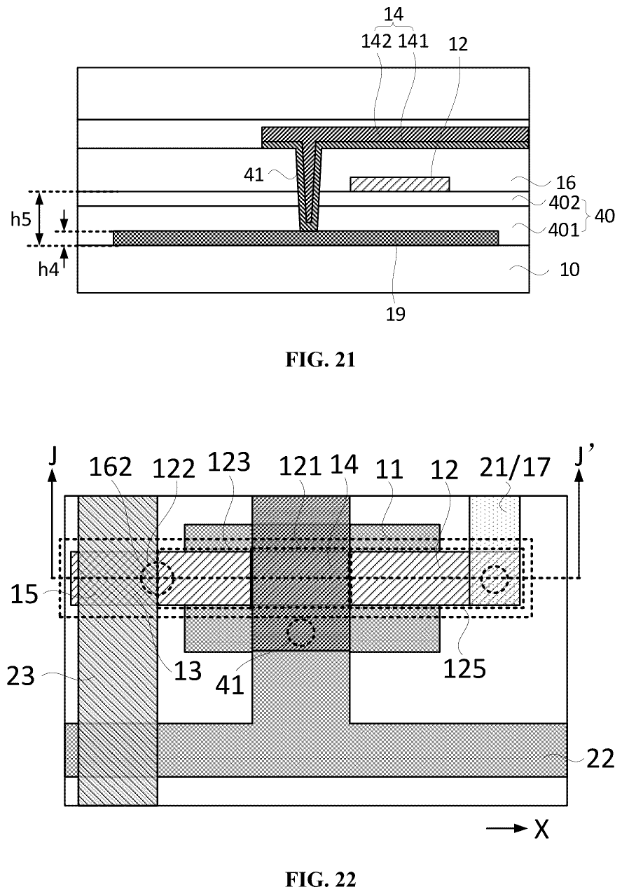

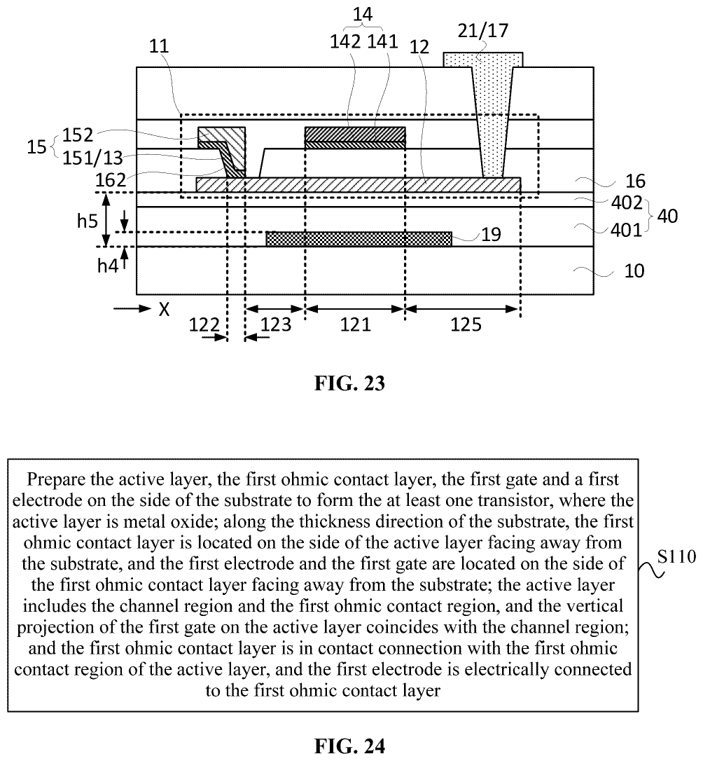

FIG. 19 is a diagram illustrating the partial structure of another array substrate according to embodiments of the present application. FIG. 20 is a sectional diagram taken along a direction H-H′ of FIG. 19. FIG. 21 is a sectional diagram taken along a direction I-I′ of FIG. 19. FIG. 22 is a diagram illustrating the partial structure of another array substrate according to embodiments of the present application. FIG. 23 is a sectional diagram taken along a direction J-J′ of FIG. 22. As shown in FIGS. 19 to 23, optionally, the transistor 11 further includes a first metal layer 19 located on a side of the active layer 12 close to the substrate 10. Along the thickness direction of the substrate 10, the first metal layer 19 at least partially overlaps the active layer 12, and the first gate 14 is electrically connected to the first metal layer 19.

In an embodiment, as shown in FIGS. 19 to 23, the side of the active layer 12 close to the substrate 10 is provided with the first metal layer 19, and the vertical projection of the first metal layer 19 on the substrate 10 at least partially overlaps the vertical projection of the active layer 12 on the substrate 10 to use the first metal layer 19 to play a certain role in blocking light emitted to the active layer 12 from the substrate 10 side of the array substrate so that the influence of the light on the threshold voltage of the transistor 11 can be reduced, and the stability of the transistor 11 can be improved.

For example, along the thickness direction of the substrate 10, the first metal layer 19 may cover the active layer 12 so that the first metal layer 19 can maximally block the light emitted to the active layer 12 from the substrate 10 side of the array substrate, thereby maximally reducing the influence of the light on the threshold voltage of the transistor 11, and improving the stability of the transistor 11.

Optionally, the material of the first metal layer 19 includes at least one of copper (Cu), aluminum (Al), molybdenum (Mo), gold (Au), niobium (Nb), or titanium (Ti), that is, the material of the first metal layer 19 may be any one of the preceding materials or an alloy of any two or more of the preceding materials to achieve a good conductivity. However, this is not limited here.

With continued reference to FIGS. 19 to 23, optionally, the thickness of the first metal layer 19 is h4, where 0<h4≤400 nm. The thickness h4 of the first metal layer 19 is less than or equal to 400 nm so that the lighter and thinner design of the array substrate can be facilitated while the process difficulty of preparing the first metal layer 19 can be reduced. However, this is not limited here.

With continued reference to FIGS. 19 to 23, the first gate 14 is electrically connected to the first metal layer 19. In this case, the transistor 11 forms a double-gate transistor so that the leakage current can be effectively reduced. Meanwhile, along the thickness direction of the substrate 10, the first gate 14 may at least partially overlap the first metal layer 19 so that the area occupied by the transistor 11 can be reduced, thereby helping increase the display resolution.

With continued reference to FIGS. 19 to 23, optionally, the array substrate further includes a second gate insulating layer 40 located between the first metal layer 19 and the active layer 12. The second gate insulating layer 40 may ensure the insulation between the first metal layer 19 and the active layer 12.

The first gate insulating layer 16 and the second gate insulating layer 40 may be each provided with a second via 41 through which the first gate 14 may be electrically connected to the first metal layer 19. However, this is not limited here.

With continued reference to FIGS. 19 to 23, optionally, the thickness of the second gate insulating layer 40 is h5, where 200 nm≤h5≤500 nm. The thickness of the second gate insulating layer 40 is relatively small, so a capacitance between the first metal layer 19 and the active layer 12 can be increased so that the on-state current of the transistor 11 can also be increased, thereby satisfying the drive requirements of the light-emitting element with a relatively small aspect ratio W/L, further reducing the volume of the transistor 11 and helping improve the display resolution.

With continued reference to FIGS. 19 to 23, optionally, the second gate insulating layer 40 includes a first insulating sub-layer 401 and a second insulating sub-layer 402 that are stacked. Along the thickness direction of the substrate 10, the first insulating sub-layer 401 is located on a side of the second insulating sub-layer 402 close to the first metal layer 19 and includes silicon nitride (SiN), and the second insulating sub-layer 402 includes silicon oxide (SiO).

Since silicon nitride (SiN) has a relatively large dielectric constant, silicon nitride has a relatively good blocking ability. The first insulating sub-layer 401 uses silicon nitride (SiN) so that the first insulating sub-layer 401 can be used for blocking impurities in the first metal layer 19, thereby preventing the performances of the transistor 11 from being affected by penetration of the impurities in the first metal layer 19 to the active layer 12.

In an embodiment, since silicon nitride (SiN) includes a large amount of impurities (such as hydrogen), and if the first insulating sub-layer 401 is in direct contact with the active layer 12, the impurities in the silicon nitride (SiN) are caused to diffuse into the active layer 12 to make the entire active layer 12 conductive, a side of the first insulating sub-layer 401 close to the active layer 12 is provided with the second insulating sub-layer 402, and the material of the second insulating sub-layer 402 uses silicon oxide (SiO) so that the active layer 12 can be prevented from being conductive due to the contact between the first insulating sub-layer 401 and the active layer 12, thereby avoiding affecting the performances of the channel region 121 due to the conducted channel region 121 of the active layer 12.

It is to be noted that in other embodiments, the first metal layer 19 may also not be electrically connected to the first gate 14, that is, the first metal layer 19 is insulated from the first gate 14, and in this case, the first metal layer 19 only plays a light-blocking role. Details are not repeated here.

Based on the same inventive concept, embodiments of the present application further provide a preparation method for an array substrate. The preparation method may be used for preparing any array substrate according to the preceding embodiments. Explanations of structures and terms the same as or corresponding to structures and terms in the preceding embodiments are not repeated here. FIG. 24 is a flowchart of a preparation method for an array substrate according to embodiments of the present application. As shown in FIG. 24, the method includes the steps below.

In S110, the active layer, the first ohmic contact layer, the first gate and the first electrode are prepared on the side of the substrate to form the at least one transistor.

The active layer is metal oxide; along the thickness direction of the substrate, the first ohmic contact layer is located on the side of the active layer facing away from the substrate, and the first electrode and the first gate are located on the side of the first ohmic contact layer facing away from the substrate; the active layer includes the channel region and the first ohmic contact region, and the vertical projection of the first gate on the active layer coincides with the channel region; and the first ohmic contact layer is in contact connection with the first ohmic contact region of the active layer, and the first electrode is electrically connected to the first ohmic contact layer.

The active layer is first prepared on the side of the substrate. The preparation material of the active layer may use metal oxide. The metal oxide may be metal oxide composed of one or a combination of Zn, Ga, In, Sn, Al, Hf, C, B, N and S so that the prepared at least one transistor can have the advantages of high carrier mobility, low deposition temperature and high transparency.

The first ohmic contact layer, the first gate and the first electrode are then prepared on the side of the active layer facing away from the substrate to form the at least one transistor. The at least one transistor may form pixel driving circuits arranged in an array to drive a light-emitting element to emit light under the action of signals of drive signal lines such as a scan signal line and a data signal line on the array substrate.

After the preparation of the active layer is completed, chemical reaction film formation may be first performed on the side of the active layer away from the substrate through chemical vapor deposition (CVD) to form the first gate insulating layer. The film formation mode has relatively few defects formed between the first gate insulating layer and the active layer.

Meanwhile, the thickness h of the prepared first gate insulating layer may satisfy 50 nm≤h≤300 nm so that the first gate insulating layer can have a relatively small thickness, thereby increasing the capacitance between the first gate and the active layer, helping increase the on-state current of the at least one transistor and satisfying the drive requirements of the light-emitting element with a relatively small channel aspect ratio.

After the preparation of the first gate insulating layer is completed, the first gate and the first electrode may be prepared on a side of the first gate insulating layer facing away from the substrate, and in this case, the first electrode and the first gate are located on the side of the active layer facing away from the substrate so that the at least one transistor can be a top-gate structure. In this way, the first gate insulating layer can be formed through the chemical reaction film formation to form relatively few defects between the first gate insulating layer and the active layer so that electron capture phenomena at the interface between the first gate insulating layer and the active layer can be reduced, the threshold voltage drift of the at least one transistor can be reduced, and the stability of the at least one transistor can be improved. Moreover, the first gate insulating layer can be provided with a relatively small thickness to increase the capacitance between the first gate and the active layer so that the on-state current of the at least one transistor can be increased, thereby satisfying the drive requirements of the light-emitting element with a relatively small aspect ratio and helping improve the display resolution.

The first electrode and the first gate may be prepared in the same process, and the finally obtained first electrode and the first gate are located in the same layer so that the process time can be shortened while the production cost and the thickness of the substrate can be reduced.

In an embodiment, after the preparation of the active layer is completed, the first ohmic contact layer is prepared on the side of the active layer facing away from the substrate, and subsequently, the first electrode is in contact connection with the first ohmic contact region of the active layer through the first ohmic contact layer to form the ohmic contact between the surface of the active layer and the first ohmic contact layer through the atomic diffusion in the first ohmic contact layer using the alloy penetration and diffusion technologies. In this way, the active layer can be conductive in the first ohmic contact region, the problem that the region of the active layer overlapping the first electrode cannot be conductive through a doping process due to the blocking of ion implantation by the first electrode can be solved, the electrical connection performance between the first electrode and the active layer can be improved, and the resistance between the first electrode and the active layer can be reduced so that the current transmission in the active layer can be easier, and the on-state current of the at least one transistor can be increased.

Optionally, that the active layer and the first ohmic contact layer are prepared on the side of the substrate includes the steps below.

The active material layer is prepared on the side of the substrate.

The first ohmic contact material layer is prepared on a side of the active material layer facing away from the substrate.

The active material layer and the first ohmic contact material layer are etched using the halftone mask in the same process to form the active layer and the first ohmic contact layer.

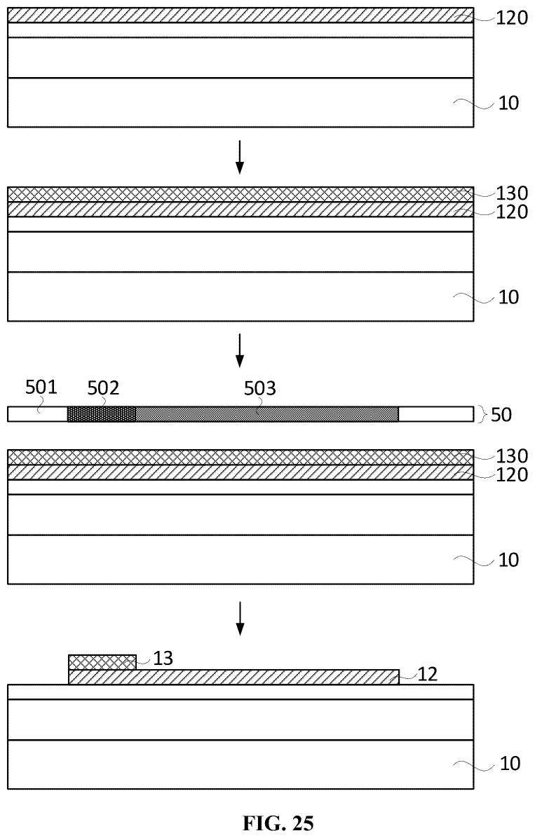

In an embodiment, FIG. 25 is a diagram illustrating a preparation method for an array substrate according to embodiments of the present application. As shown in FIG. 25, the entire active material layer 120 may be prepared on the side of the substrate 10, and the entire first ohmic contact material layer 130 is prepared on the side of the active material layer 120 facing away from the substrate 10, sequentially.

The active material layer 120 and the first ohmic contact material layer 130 are then exposed using the halftone mask (HTM) 50 in the same process to form the active layer 12 and the first ohmic contact layer 13 in the same process. With such a configuration, the number of processes can be reduced, and the process time can be shortened.

Exemplarily, the halftone mask 50 may include a first segment 501, a second segment 502 corresponding to a contact region between the active layer 12 and the first ohmic contact layer 13, and a third segment 503 corresponding to anon-contact region of the active layer 12 and the first ohmic contact layer 13. The transmittance of the first segment 501 is greater than the transmittance of the third segment 503, and the transmittance of the third segment 503 is greater than the transmittance of the second segment 502.

When the active material layer 120 and the first ohmic contact material layer 130 are exposed using the halftone mask 50, the etched degree of the active material layer 120 and the first ohmic contact material layer 130 corresponding to the first segment 501 is greater than the etched degree of the active material layer 120 and the first ohmic contact material layer 130 corresponding to the third segment 503, and the etched degree of the active material layer 120 and the first ohmic contact material layer 130 corresponding to the third segment 503 is greater than the etched degree of the active material layer 120 and the first ohmic contact material layer 130 corresponding to the second segment 502. In this way, all the active material layer 120 and the first ohmic contact material layer 130 corresponding to the first segment 501 can be etched, and the first ohmic contact material layer 130 corresponding to the third segment 503 can be etched so that the active layer 12 and the first ohmic contact layer 13 can be finally formed.

Optionally, that the active layer, the first ohmic contact layer and the first electrode are prepared on the side of the substrate includes the steps below.

The active layer is prepared on the side of the substrate.

The first gate insulating layer is prepared on the side of the active layer away from the substrate.

A first via is prepared in the first gate insulating layer.

The first ohmic contact layer and the first electrode are prepared on the side of the first gate insulating layer facing away from the substrate, where the first ohmic contact layer is in contact connection with the active layer through the first via, and along the direction of the first ohmic contact region pointing to the channel region, the first boundary of the first electrode is located on the side of the second boundary of the first via away from the channel region, the first boundary is the boundary of the side of the first electrode close to the channel region, and the second boundary is the boundary of the side of the first via close to the channel region.

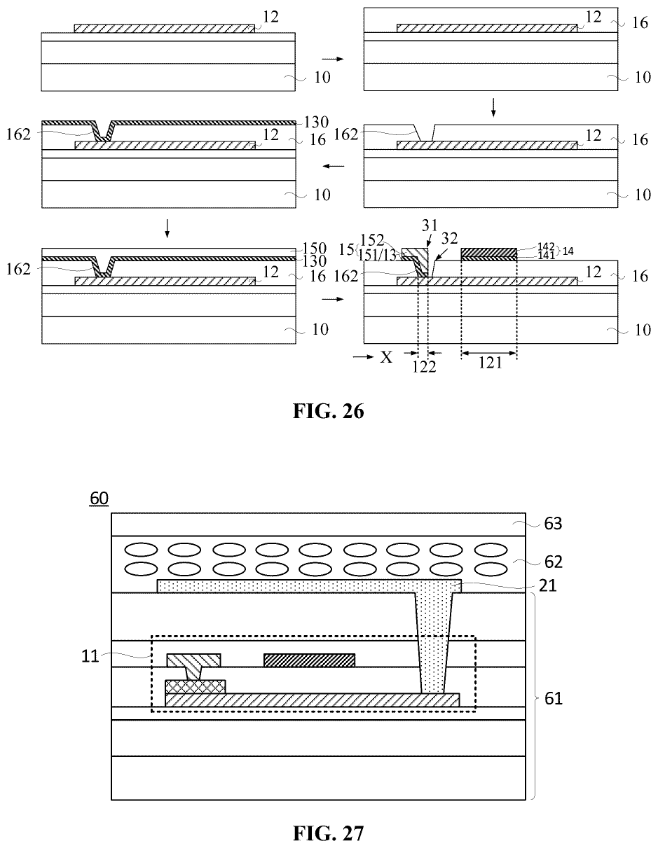

In an embodiment, FIG. 26 is a diagram illustrating a preparation method for another array substrate according to embodiments of the present application. As shown in FIG. 26, the active layer 12 and the first gate insulating layer 16 are sequentially prepared on the side of the substrate 10, and the first via 162 is prepared on the first gate insulating layer 16. The first ohmic contact layer 13 and the first electrode 15 are then prepared on the first gate insulating layer 16. The first ohmic contact layer 13 overlaps the active layer 12 through the first via 162. The region in which the first ohmic contact layer 13 is in contact with the active layer 12 is the first ohmic contact region 122.

As shown in FIG. 26, when the first ohmic contact layer 13 and the first electrode 15 are prepared, the entire first ohmic contact material layer 130 and the entire first electrode material layer 150 may be first sequentially prepared on the side of the substrate 10 and are then etched in the same process to form the first ohmic contact layer 13 and the first electrode 15 in the same process so that the process time can be shortened.

With continued reference to FIG. 26, along the direction of the first ohmic contact region 122 pointing to the channel region 121 (such as the first direction X), the first boundary 31 of the side of the first electrode 15 close to the channel region 121 is located on the side of the second boundary 32 away from the channel region 121, where the second boundary 32 is on the side of the first via 162 close to the channel region 121. In this case, along the thickness direction of the substrate 10, the first via 162 has a region that does not overlap the first electrode 15, that is, the first electrode 15 does not cover the entire first via 162, and the region in which the first via 162 does not overlap the first electrode 15 is located on the side of the first electrode 15 close to the channel region 121.

Optionally, as shown in FIG. 26, when the first ohmic contact layer 13 and the first electrode 15 are prepared, the first gate 14 may be simultaneously prepared. In an embodiment, when the first ohmic contact material layer 130 and the first electrode material layer 150 are etched, the second conductive base layer 141 and the second conductive electrode layer 142 are simultaneously formed to form the first gate 14.

With continued reference to FIG. 10, after the first gate 14 is prepared, and when ion implantation is performed on the active layer 12 through a doping process, an ion beam 33 is emitted to the entire surface of the at least one transistor 11, and the first gate 14 is used as the blocking layer so that doped ions cannot be implanted into the region of the active layer 12 blocked by the first gate 14, thereby forming the channel region 121. In this case, the first electrode 15 does not block the region between the first ohmic contact region 122 and the channel region 121 of the active layer 12 so that the entire region between the first ohmic contact region 122 and the channel region 121 can be conductive, helping reduce the connection resistance between the first electrode 15 and the active layer 12, and so that the current transmission in the active layer 12 can be easier, thereby increasing the on-state current of the at least one transistor 11.

Optionally, after the active layer, the first ohmic contact layer, the first gate and the first electrode are prepared on the side of the substrate, the method further includes the steps below.

Ion implantation is performed on the active layer using the first gate as the blocking layer to form the first doping region.

In an embodiment, with continued reference to FIGS. 7 and 10, after the first gate 14 is prepared, an ion beam 33 may be emitted to the entire side surface of the at least one transistor 11, and the first gate 14 is used as the blocking layer so that doped ions cannot be implanted into the region of the active layer 12 blocked by the first gate 14, thereby forming the channel region 121, and so that the doped ions can be implanted into the region of the active layer 12 not blocked by the first gate 14, the first electrode 15 and the first ohmic contact layer 13 to conduct the region, thereby forming the first doping region 123. With such a configuration, along the first direction X, the boundary between the conducted region of the active layer 12 and the channel region 121, that is, the boundary between the first doping region 123 and the channel region 121, just coincides with the vertical projection of the boundary of the first gate 14 on the active layer 12 so that the conducted region of the active layer 12 can be prevented from affecting the true length of the channel region 121 due to an overlapping region between the conducted region and the first gate 14 caused by a process error, and so that the conducted region of the active layer 12 can be prevented from increasing the resistance between the active layer 12 and the first electrode 15 due to a gap between the conducted region and the channel region 121 caused by a process error, and the on-state current of the at least one transistor 11 can be ensured to satisfy the drive requirements of the light-emitting element.

The mode of performing the ion implantation on the active layer 12 using the first gate 14 as the blocking layer can omit a process of a mask so that the preparation process of the at least one transistor 11 can be simplified.

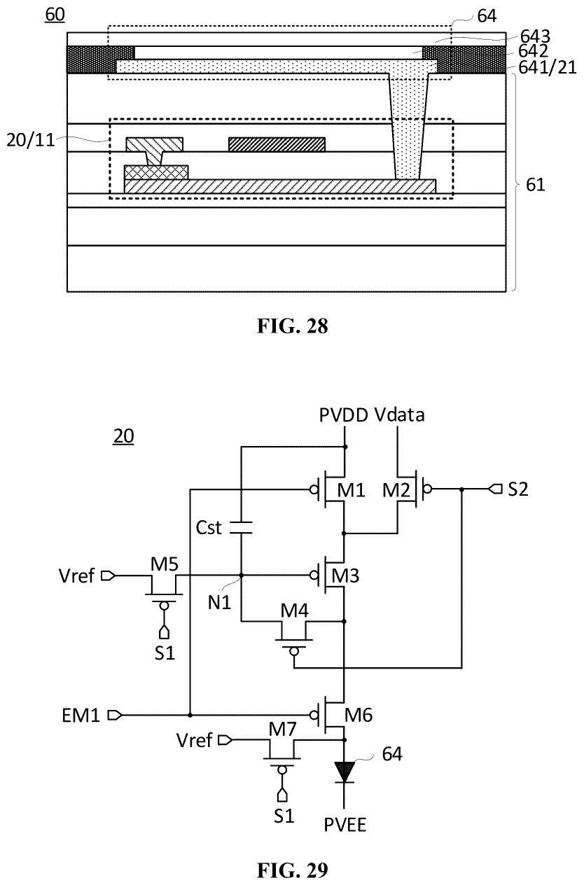

Based on the same inventive concept, embodiments of the present application further provide a display panel. FIG. 27 is a diagram illustrating the structure of a display panel according to embodiments of the present application. FIG. 28 is a diagram illustrating the structure of another display panel according to embodiments of the present application. As shown in FIGS. 27 and 28, the display panel 60 includes the array substrate 61 described in any embodiment of the present application. Therefore, the display panel 60 according to this embodiment of the present application has the technical effect of the technical solution in any one of the preceding embodiments. Explanations of structures and terms the same as or corresponding to structures and terms in the preceding embodiments are not repeated here.

Exemplarily, as shown in FIG. 27, the display panel 60 may be the liquid crystal display (LCD) panel and further includes a liquid crystal layer 62 and an opposite substrate 63. The liquid crystal layer is located between the array substrate 61 and the opposite substrate 63. The opposite substrate 63 and the array substrate 61 are opposite to form a liquid crystal cell to accommodate the liquid crystal layer 62.

The transistor 11 of the at least one transistor 11 is electrically connected to the pixel electrode 21. A drive voltage is applied to the pixel electrode 21 through the transistor 11 so that an electric field can be formed between the pixel electrode 21 and a common electrode (not shown in the figures). The electric field can deflect liquid crystal molecules in the liquid crystal layer 62. After the liquid crystal molecules are deflected, light generated by the backlight assemblies transmits through the display panel. Degrees of deflections of the liquid crystal molecules may be different by adjusting the drive voltage to change the sizes of the electric field. The transmittance of the display panel and the amount of light transmitted by the backlight assembly through the display panel varies with the degree of the deflection of the liquid crystal molecules. Therefore, an image can be displayed.

The opposite substrate 63 may be a color filter substrate provided with a black matrix and a photoresist layer to display a colorful image of the display panel.

In addition, the common electrode may be disposed on the array substrate 61 or the opposite substrate 63. This is not limited in this embodiment of the present application.

In other embodiments, as shown in FIG. 28, the display panel 60 may also be an organic light-emitting diode (OLED) display panel and includes the pixel driving circuit 20 and a light-emitting element 64. The pixel driving circuit 20 includes the at least one transistor 11. The pixel driving circuit 20 is electrically connected to the light-emitting element 64. An illustration is made using an example in which the light-emitting element 64 is an organic light-emitting diode. The light-emitting element 64 may include an anode 641, a light-emitting layer 642 and a cathode 643 that are stacked. The pixel driving circuit 20 is used for transmitting a drive current to the light-emitting element 64 under the action of signals of drive signal lines (such as a scan signal line, a data signal line or, a power signal line) on the display panel to provide the drive current for the light-emitting element 64. In this case, electrons and holes are implanted into the light-emitting layer 642 from the cathode 643 and the anode 641 respectively to form excitons inside the light-emitting layer 642 and excite light-emitting molecules so that the light-emitting layer 642 can emit visible light.

With continued reference to FIG. 28, the anode 641 and the preceding pixel electrode 21 may be the same film structure. However, this is not limited here.

It is to be noted that the number of transistors 11 in the pixel driving circuit 20 may be disposed according to actual requirements. This is not limited in this embodiment of the present application.

Exemplarily, FIG. 29 is a diagram illustrating the structure of a pixel driving circuit according to embodiments of the present application. As shown in FIG. 29, an illustration is made using an example in which the pixel driving circuit 20 is a 7T1C circuit. The pixel driving circuit 20 may include a drive transistor M3, a first light emission control transistor M1, a second light emission control transistor M6, a first reset transistor M5, a data write transistor M2, an additional transistor M4, a light emission reset transistor M7 and a first capacitance Cst.

The drive transistor M3 and the light-emitting element 64 are connected in series between a first power signal line PVDD and a second power signal line PVEE.

The gate of the first light emission control transistor M1 is electrically connected to a first light emission control signal line EM1, the first electrode of the first light emission control transistor M1 is electrically connected to the first power signal line PVDD, and the second electrode of the first light emission control transistor M1 is electrically connected to the first electrode of the drive transistor M3.

The gate of the second light emission control transistor M6 is electrically connected to the first light emission control signal line EM1, the first electrode of the second light emission control transistor M6 is electrically connected to the second electrode of the drive transistor M3, and the second electrode of the second light emission control transistor M6 is electrically connected to the light-emitting element 64.

The gate of the first reset transistor M5 is electrically connected to a first scan signal line S1, the first electrode of the first reset transistor M5 is electrically connected to a reference signal line Vref, and the second electrode of the first reset transistor M5 and the gate of the drive transistor M3 are connected to a first node N1.

The gate of the data write transistor M2 is electrically connected to a second scan signal line S2, the first electrode of the data write transistor M2 is electrically connected to a data signal line Vdata, and the second electrode of the data write transistor M2 is electrically connected to the first electrode of the drive transistor M3.

The gate of the additional transistor M4 is electrically connected to the second scan signal line S2, the first electrode of the additional transistor M4 is electrically connected to the second electrode of the drive transistor M3, and the second electrode of the additional transistor M4 is electrically connected to the first node N1.

The gate of the light emission reset transistor M7 is connected to the first scan signal line S1, the first electrode of the light emission reset transistor M7 is electrically connected to the reference signal line Vref, and the second electrode of the light emission reset transistor M7 is electrically connected to the anode of the light-emitting element 64.

A terminal of the first capacitance Cst is electrically connected to the first power signal line PVDD, and the other terminal of the first capacitance Cst is electrically connected to the first node N1.

The driving process of the pixel driving circuit 20 is, for example, the following.

In the initialization stage, a first scan signal on the first scan signal line S1 turns on the first reset transistor M5, and a reference voltage on the reference signal line Vref is applied to the terminal of the first capacitance Cst through the first reset transistor M5, that is, the potential of the first node N1 is the reference voltage, so that the first node N1 can be reset. At this time, the potential of the gate of the drive transistor M3 is also the reference voltage.

Meanwhile, in the initialization stage, a first scan signal Scan1 on the first scan signal line S1 also turns on the light emission reset transistor M7, so the light emission reset transistor M7 writes the reference voltage on the reference signal line Vref into the anode of the light-emitting element 64 so that the potential of the anode of the light-emitting element 64 can be reset, thereby reducing the influence of the voltage of the anode of the light-emitting element 64 of the previous frame on the voltage of the anode of the light-emitting element 64 of the next frame and helping improve the display uniformity.

In the data signal voltage write stage, a second scan signal on the second scan signal line S2 turns on the data write transistor M2 and the additional transistor M4, and, at this time, the potential of the gate of the drive transistor M3 is the reference voltage, and the drive transistor M3 is also turned on, so a data signal voltage on the data signal line Vdata is applied to the first node N1 through the data write transistor M2, the drive transistor M3 and the additional transistor M4 so that the data signal voltage can be written into the first capacitance Cst.

In the light emission stage, a first light emission control signal on the light emission control signal line EM1 turns on the first light emission control transistor M1 and the second light emission control transistor M6, and a current path is formed between the first power signal line PVDD, the first light emission control transistor M1, the second light emission control transistor M6, the drive transistor M3, the light-emitting element 64 and the second power signal line PVEE so that a drive current generated by the drive transistor M3 can be provided for the light-emitting element 64, thereby driving the light-emitting element 64 to emit light through the drive transistor M3 and fulfilling the light emission and display function of the display panel.

The specific structure of the pixel driving circuit 20 is not limited to the preceding 7T1C circuit and may be disposed by those skilled in the art according to actual requirements.

It is to be noted that all the transistors in the pixel driving circuit 20 may each use the transistor according to any one of the preceding embodiments, or only part of the transistors in the pixel driving circuit 20 may each use the transistor according to any one of the preceding embodiments. This is not limited in this embodiment of the present application.

Exemplarily, as shown in FIG. 29, the additional transistor M4 and the first reset transistor M5 may use the transistor according to any one of the preceding embodiments to reduce the leakage current of the first node N1, thereby reducing the influence of the leakage current on the display effect.

In other embodiments, the display panel 60 may also use a display panel of another type. This is not limited in this embodiment of the present application.

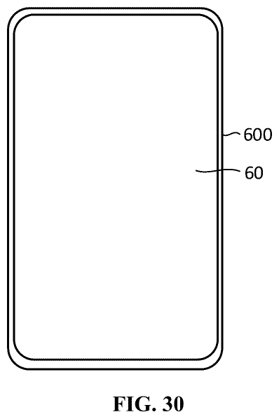

Based on the same inventive concept, embodiments of the present application further provide a display device. FIG. 30 is a diagram illustrating the structure of a display device according to embodiments of the present application. As shown in FIG. 30, the display device 600 includes the display panel 60 according to any embodiment of the present application. Therefore, the display device 600 according to this embodiment of the present application has the technical effect of the technical solution in any one of the preceding embodiments. Explanations of structures and terms the same as or corresponding to structures and terms in the preceding embodiments are not repeated here.

The display device 600 according to this embodiment of the present application may be the cellphone shown in FIG. 30 or may be any other electronic product having a display function. The electronic product includes, but is not limited to, a television set, a laptop, a desktop display, a tablet, a digital camera, a smart bracelet, smart glasses, an in-vehicle display, a medical device, an industrial control device, or a touch interactive terminal. This is not specially limited in this embodiment of the present application.

It is to be understood that various forms of processes shown in the preceding may be adopted with steps reordered, added, or deleted. For example, the steps described in the present application may be performed in parallel, sequentially, or in different orders, as long as the desired results of technical solutions of the present application can be achieved, and no limitation is imposed herein.

The preceding embodiments do not limit the scope of the present application. It is to be understood by those skilled in the art that various modifications, combinations, sub-combinations and substitutions may be performed according to design requirements and other factors. Any modification, equivalent substitution, improvement, or the like made within the spirit and principle of the present application is within the scope of the present application.

What is claimed is:

1. An array substrate, comprising a substrate and at least one transistor located on a side of the substrate, wherein each transistor of the at least one transistor comprises an active layer, a first ohmic contact layer, a first gate and a first electrode, and the active layer comprises metal oxide;
along a thickness direction of the substrate, the first ohmic contact layer is located on a side of the active layer facing away from the substrate, and the first electrode and the first gate are located on a side of the first ohmic contact layer facing away from the substrate;
the active layer comprises a channel region and a first ohmic contact region, and a vertical projection of the first gate on the active layer overlaps the channel region; and
the first ohmic contact layer is in contact connection with the first ohmic contact region of the active layer, and the first electrode is electrically connected to the first ohmic contact layer.

2. The array substrate according to claim 1, wherein
along a first direction, a distance from a boundary of a side of the first ohmic contact layer close to the channel region is d1, and a distance from a boundary of a side of the first electrode close to the channel region is d2, wherein d1≤d2; and
the first direction is a direction of the first ohmic contact region pointing to the channel region.

3. The array substrate according to claim 1, wherein
the first gate and the first electrode are located in a same layer.

4. The array substrate according to claim 1, wherein
the array substrate further comprises a first gate insulating layer, and along the thickness direction of the substrate, the first gate insulating layer is located between the first electrode and the active layer, and the first ohmic contact layer is located between the first gate insulating layer and the active layer; and
a vertical projection of the first ohmic contact layer on the active layer coincides with the first ohmic contact region.

5. The array substrate according to claim 4, wherein
the first ohmic contact region abuts onto the channel region.

6. The array substrate according to claim 4, wherein
the active layer further comprises a first doping region abutting onto the first ohmic contact region and the channel region separately.

7. The array substrate according to claim 1, wherein
the array substrate further comprises a first gate insulating layer, and along the thickness direction of the substrate, the first gate insulating layer is located between the first electrode and the active layer, and the first ohmic contact layer is located between the first gate insulating layer and the first electrode;
the first gate insulating layer is provided with a first via through which the first ohmic contact layer is in contact connection with the active layer;
along a first direction, a first boundary of the first electrode is located on a side of a second boundary of the first via facing away from the channel region, wherein the first boundary is a boundary of a side of the first electrode close to the channel region, and the second boundary is a boundary of a side of the first via close to the channel region; and
the first direction is a direction of the first ohmic contact region pointing to the channel region.

8. The array substrate according to claim 7, wherein
a length of the first electrode in the first direction is d5; and
along the thickness direction of the substrate, a length of an overlapping region between the first electrode and the first via in the first direction is d6, wherein d6≥(½)*d5.

9. The array substrate according to claim 7, wherein
along the thickness direction of the substrate, a length of an overlapping region between the first electrode and the first via in the first direction is d6; and
along the thickness direction of the substrate, within a region in which the first via is located, a length of a region other than the overlapping region between the first via and the first electrode in the first direction is d7,
wherein d7≥d6.

10. The array substrate according to claim 7, wherein
along the thickness direction of the substrate, the first electrode and the first via overlap, and a length of an overlapping region between the first electrode and the first via in the first direction is d6; and
a length in the first direction of a region in which the first via is located is d8,
wherein 10%≤d6/d8≤90%.

11. The array substrate according to claim 7, wherein
the first electrode comprises a first conductive base layer and a first conductive electrode layer that are stacked, and along the thickness direction of the substrate, the first conductive base layer is located on a side of the first conductive electrode layer close to the first gate insulating layer, and the first conductive base layer is in contact connection with the first conductive electrode layer; and
the first ohmic contact layer and the first conductive base layer have a same film structure.

12. The array substrate according to claim 1, wherein
the each transistor further comprises a second electrode and a second ohmic contact layer;
the second ohmic contact layer is located on the side of the active layer facing away from the substrate, and the second electrode is located on a side of the second ohmic contact layer facing away from the substrate;
the active layer further comprises a second ohmic contact region located on a side of the channel region away from the first ohmic contact region; and
the second ohmic contact layer is in contact connection with the second ohmic contact region of the active layer, and the second electrode is electrically connected to the second ohmic contact layer.

13. The array substrate according to claim 1, wherein
the each transistor further comprises a second electrode, and along the thickness direction of the substrate, the second electrode is located on a side of the first gate facing away from the substrate;
the active layer further comprises a second doping region located on a side of the channel region facing away from the first ohmic contact region; and
the second electrode and the active layer are in contact connection in the second doping region.

14. The array substrate according to claim 1, wherein
the each transistor further comprises a first metal layer located on a side of the active layer close to the substrate; and
along the thickness direction of the substrate, the first metal layer at least partially overlaps the active layer, and the first gate is electrically connected to the first metal layer.

15. A preparation method for an array substrate, comprising:
preparing an active layer, a first ohmic contact layer, a first gate and a first electrode on a side of the substrate to form at least one transistor,
wherein the active layer is metal oxide; along a thickness direction of the substrate, the first ohmic contact layer is located on a side of the active layer facing away from the substrate, and the first electrode and the first gate are located on a side of the first ohmic contact layer facing away from the substrate; the active layer comprises a channel region and a first ohmic contact region, and a vertical projection of the first gate on the active layer coincides with the channel region; and the first ohmic contact layer is in contact connection with the first ohmic contact region of the active layer, and the first electrode is electrically connected to the first ohmic contact layer.

16. The preparation method according to claim 15, wherein
preparing the active layer and the first ohmic contact layer on the side of the substrate comprises:
preparing an active material layer on the side of the substrate;
preparing a first ohmic contact material layer on a side of the active material layer facing away from the substrate; and
etching the active material layer and the first ohmic contact material layer using a halftone mask in a same process to form the active layer and the first ohmic contact layer.

17. The preparation method according to claim 15, wherein
preparing the active layer, the first ohmic contact layer and the first electrode on the side of the substrate comprises:
preparing the active layer on the side of the substrate;
preparing a first gate insulating layer on the side of the active layer facing away from the substrate;
preparing a first via on the first gate insulating layer; and
preparing the first ohmic contact layer and the first electrode on a side of the first gate insulating layer facing away from the substrate, wherein the first ohmic contact layer is in contact connection with the active layer through the first via, and along a direction of the first ohmic contact region pointing to the channel region, a first boundary of the first electrode is located on a side of a second boundary of the first via facing away from the channel region, the first boundary is a boundary of a side of the first electrode close to the channel region, and the second boundary is a boundary of a side of the first via close to the channel region.

18. The preparation method according to claim 15, wherein
after preparing the active layer, the first ohmic contact layer, the first gate and the first electrode on the side of the substrate, the method further comprises:
performing ion implantation on the active layer using the first gate as a blocking layer to form a first doping region.

19. A display panel, comprising an array substrate, wherein the array substrate comprises a substrate and at least one transistor located on a side of the substrate, wherein each transistor of the at least one transistor comprises an active layer, a first ohmic contact layer, a first gate and a first electrode, and the active layer comprises metal oxide;
along a thickness direction of the substrate, the first ohmic contact layer is located on a side of the active layer facing away from the substrate, and the first electrode and the first gate are located on a side of the first ohmic contact layer facing away from the substrate;
the active layer comprises a channel region and a first ohmic contact region, and a vertical projection of the first gate on the active layer overlaps the channel region; and
the first ohmic contact layer is in contact connection with the first ohmic contact region of the active layer, and the first electrode is electrically connected to the first ohmic contact layer.

20. A display device, comprising the display panel according to claim 19.
